(19) United States
(12) Patent Application Publication
(10) Pub. No.: US 2025/0183920 A1
(43) Pub. Date: Jun. 5, 2025

(54) BYTE ERROR CORRECTION

(71) Applicant: Infineon Technologies AG, Neubiberg (DE)

(72) Inventors: Thomas Kern, Aschheim (DE); Alexander Klockmann, Taufkirchen (DE); Michael Goessel, Mahlow (DE)

(21) Appl. No.: 18/958,072

(22) Filed: Nov. 25, 2024

(30) Foreign Application Priority Data
Nov. 30, 2023 (DE) 10 2023 212 041.0

(51) Int. Cl. H03M 13/00

(52) U.S. Cl. CPC H03M 13/6516

(57) ABSTRACT

An approach corrects at least one byte error in a binary sequence, the binary sequence comprising multiple bytes and being a codeword of an error code if there is no error. The approach comprises: (i) determining at least one byte error position signal indicating whether or not a byte of the binary sequence is erroneous, (ii) determining at least one byte error correction value on the basis of which an erroneous byte position identified by using the byte error position signal is able to be corrected, (iii) wherein the at least one byte error correction value is determined by determining a first value, a second value and a third value for each of at least three byte positions according to a coefficient of the locator polynomial, and (iv) correcting the at least one byte error on the basis of the at least one byte error correction value.

### REFERENCE TO RELATED APPLICATIONS

This application claims priority to German Patent Application 10 2023 212 041.0, filed on Nov. 30, 2023, the contents of which are hereby incorporated by reference in their entirety.

### TECHNICAL FIELD

It is known practice to recognize errors in data that are available in the form of bytes on a byte-by-byte basis and to correct the errors on a byte-by-byte basis. A byte can comprise at least two bits. At least one error in at least one bit of a byte is referred to as a byte error. If at least one bit of a byte is erroneous, there is a byte error. If only at least one bit of a single byte is erroneous, this corresponds to a 1-byte error.

The correction of 1-byte errors is described by way of example in [Bossen, D.: b-Adjacent Error Correction, IBM J. Res. Dev., July 1970, pages 402 to 408].

If bits of two different bytes are erroneous, this corresponds to a 2-byte error. Accordingly, it holds true that there is a k-byte error if bits in k bytes are erroneous (i.e. at least one bit in each of the k bytes has an error).

It is a general motivation to perform the error correction for possibly erroneous bytes quickly. This holds true, by way of example, when data that are available in bytes are read from a memory in parallel and are meant to be provided in parallel. In such a scenario, it may be advantageous to perform the error correction in parallel as well.

In parallel, in this context, means in particular that an error correction or part of the error correction for at least two bytes is performed at least to some extent simultaneously (for example including, at least to some extent, at overlapping times).

Byte error correction can be carried out by using a Reed-Solomon code, for example.

OKANO [Okano, H., Imaⁱ, H.: A Construction Method of High-Speed Decoders Using ROM's for Bose-Chaudhuri-Hocquengiem and Reed-Solomon Codes, IEEE TRANSACTIONS ON COMPUTERS, VOL. C-36, NO. 10, October 1987, pages 1165 to 1171] describes a circuit arrangement for correcting 2-byte errors using a Reed-Solomon code. A disadvantage in this case is that the correction of 2-byte errors described in OKANO is relatively slow.

### BACKGROUND

One advantage of the present disclosure is to avoid disadvantages of known solutions for correcting byte errors and in particular to permit error correction of errors in multiple bytes as quickly as possible.

In particular, it is an object to provide an error correction for m-byte errors where m≥2 for memory cells, e.g. MRAM memory cells, RRAM memory cells, etc. and thus to increase the reliability of data read from the memory cells.

### SUMMARY

A circuit arrangement is proposed for correcting at least one byte error in a binary sequence comprising multiple bytes, the binary sequence being a codeword of an error code if there is no error, the circuit arrangement being configured
to determine at least one byte error position signal indicating whether or not a byte of the binary sequence is erroneous,
to determine at least one byte error correction value on the basis of which an erroneous byte position identified by using the byte error position signal is able to be corrected,
wherein the at least one byte error correction value is determined by determining a first value, a second value and a third value for each of at least three byte positions according to a coefficient of the locator polynomial,
to correct the at least one byte error on the basis of the at least one byte error correction value.

It will be noted here that one byte error position signal can be determined per byte of the binary sequence. Therefore, each byte of the binary sequence has a linked, or associated, byte error position signal. The value of the byte error position signal indicates whether or not the byte linked to the byte error position signal has an error.

By way of example, the error code is an error-correcting and/or error-recognizing code. By way of example, the error code used can be a Reed-Solomon code.

One development is that the first value comprises: a correction value A multiplied by a first constant, the first constant being determined by the erroneous byte position.

One development is that the third value comprises: a correction value C multiplied by a second constant, the second constant being determined by the erroneous byte position.

One development is that the multiplications by the constants are multiplications in the Galois field GF(2^{m}) where m≥2.

One development is that the byte error correction value is determined in accordance with:

$$v ( L ) = {α}^{L} \cdot A + B + {α}^{2 L} \cdot C , \qquad ( 1 )$$

where
a^{L} denotes the first constant,
a^{2L} denotes the second constant,
A, C denote the correction values,
B denotes the second value and
+denotes the addition in the Galois field GF(2^{m}) where m≥2.

One development is that the correction values A and C and the second value are the same for different byte positions.

One development is that the second constant is the square of the first constant.

One development is that a correction is made for byte positions for which the byte error correction value is not equal to zero.

One development is that a 3-byte error is able to be corrected using three byte error position signals.

One development is that at least some byte error correction values are determined at overlapping times.

In particular, at least two byte error correction values can be determined in parallel. In parallel, in this context, means in particular that at least some values are determined in parallel with one another, that is to say, by way of example, simultaneously or at least to some extent simultaneously.

One development is that the byte error position signal is able to be determined using components of an error syndrome of the error code.

One development is that at least one of the byte error correction values is determined for at least one correct byte.

One development is that a 3-byte error is corrected.

One development is that the error code is a Reed-Solomon code in a Galois field GF(2^{m}), where m≥2, that can correct at least3-byte errors.

A method is also proposed for correcting at least one byte error in a binary sequence comprising multiple bytes, the binary sequence being a codeword of an error code if there is no error, comprising the steps of:
determining at least one byte error position signal indicating whether or not a byte of the binary sequence is erroneous,
determining at least one byte error correction value on the basis of which an erroneous byte position identified by using the byte error position signal is able to be corrected,
wherein the at least one byte error correction value is determined by determining a first value, a second value and a third value for each of at least three byte positions according to a coefficient of the locator polynomial,
correcting the at least one byte error on the basis of the at least one byte error correction value.

The above explanations relating to the apparatus hold true mutatis mutandis for the method. The steps of the method that are described here can be carried out by using the apparatus.

The properties, features and advantages of this invention that are described above and the way in which they are achieved are described hereinbelow in association with a schematic description of exemplary embodiments, which are explained in more detail in association with the drawings. For the sake of clarity, elements that are the same or have the same action may be provided with the same reference signs.

### BRIEF DESCRIPTION OF THE DRAWINGS

In the drawings:

FIG. 1 shows an illustrative circuit arrangement for the parallel formation of byte error position signals for 2-byte errors,

FIG. 2 shows an alternative configuration of the circuit arrangement shown in FIG. 1,

FIG. 3 shows another configuration of the circuit arrangement shown in FIG. 1 with a central circuit part,

FIG. 4 shows an alternative illustrative implementation of the central circuit part shown in FIG. 3,

FIG. 5 shows an example of a circuit arrangement for byte error correction for 2-byte errors,

FIG. 6 shows an example of an implementation of the subcircuit shown in FIG. 5 for forming the byte error correction value,

FIG. 7 shows another example of an implementation of the subcircuit shown in FIG. 5 for forming the byte error correction value,

FIG. 8 shows an example of a correction circuit for 1-byte errors and 2-byte errors using a circuit arrangement for forming byte error position signals for 2-byte errors,

FIG. 9 shows an illustrative correction circuit for 1-byte errors, 2-byte errors through to t-byte errors using a circuit arrangement for forming byte error position signals for 2-byte errors,

FIG. 10 shows an illustrative configuration of the subcircuit shown in FIG. 8,

FIG. 11 shows an error recognition circuit,

FIG. 12 shows an error recognition circuit for recognizing 3-byte errors,

FIG. 13 shows a table illustrating different forms of representation of elements of a Galois field GF(2^{m}) where m=5,

FIG. 14 shows an illustrative configuration for forming the coefficients σ₁ and σ₂,

$$\frac{{s}_{1}}{{σ}_{1}} ,$$

FIG. 15 shows an illustrative configuration for forming the term

$$\frac{{s}_{2}}{{σ}_{1}} + {s}_{1} ,$$

FIG. 16 shows an illustrative configuration for forming the term

FIG. 17 shows an illustrative configuration for forming the values of the locator polynomial on the basis of its coefficients σ₁ and σ₂ for byte position i and j,

FIG. 18 shows an illustrative configuration for forming the byte error correction values a(k) for the byte positions i and j,

FIG. 19 shows an illustrative configuration for correcting a byte error at the positions i and L, FIG. 20 shows an illustrative configuration for determining the correction values A, B and C.

### DETAILED DESCRIPTION

By way of example, the text below discusses correction of byte errors using a Reed-Solomon code. A byte in this case can comprise multiple bits.

For each correctable byte position, a signal (also referred to as a byte error position signal) is determined on the basis of which it is possible to establish whether or not the byte is erroneous. By way of example, the byte error position signal has the value 1 when the byte is erroneous or the value 0 when the byte is not erroneous.

The byte error position signal is preferably determined by a value of a locator polynomial. In the case of byte-error-correcting codes, an individual locator polynomial can be used for any number of errors.

It is therefore proposed, in particular, that a byte error position signal be determined for correctable byte positions of a byte-error-correcting code, the byte-error-correcting code being able to correct in particular at least two byte errors.

A correctable byte position in this context is a byte position for which there is provision for a correction when an error occurs that is able to be corrected by the byte-error-correcting code.

By way of example, the bytes are data bytes, a combination of data bytes and check bytes or a subset thereof. Data bytes preferably contain payload data.

A byte error correction value can be determined for a byte position, the byte error correction value being taken as a basis for correcting the byte position when an error has occurred there. The byte error position signal indicates whether an error has occurred for a byte, and the byte error correction value can be used to correct this error. The byte error position signal can thus be used to hide (mask) individual byte positions at which no correction is meant to take place.

In particular, it is an option for a byte error correction value that is not meant to be used for correction at a byte position (e.g. because this byte position is not erroneous) to be multiplied by 0. In this respect, multiplying the byte error correction value by 0 also corresponds to not using the byte error correction value at a byte position.

### Reed-Solomon Code, General Description

A few concepts and properties of Reed-Solomon codes are explained below.

By way of example,
t-byte-error-correcting codes and
t-byte-error-correcting and (t+1)-byte-error-recognizing codes
   are considered. In particular, the cases t=2 and t=1 are taken into account.

By way of example, the byte-error-correcting codes used can be known Reed-Solomon codes. For Reed-Solomon codes, reference is made by way of illustration to [Lin, S., Costello, D.: Error Control Coding, Prentice Hall, 1983, pages 170 to 177] or [Wicker, S.: Error Control Systems for Digital Communication and Storage, Prentice Hall, 1995, pages 214 to 224].

A 1-byte-error-correcting and 2-byte-error-recognizing Reed-Solomon code has an H matrix H_{Byte}*as follows:

$${H}_{Byte}^{*} = ( \begin{matrix}{α}^{0} & {α}^{1} & {α}^{2} & … & {α}^{{2}^{m} - 2} \\ {α}^{0} & {α}^{2} & {α}^{4} & … & {α}^{2 ( {2}^{m} - 2 )} \\ {α}^{0} & {α}^{3} & {α}^{6} & … & {α}^{3 ( {2}^{m} - 2 )}\end{matrix} ) \qquad ( 2 )$$

Here, aⁱ are elements of the Galois field GF(2^{m}). These are present in an exponential representation, for example. α can be a primitive element of the Galois field GF(2^{m}). The exponents j of a^{j} should be interpreted modulo 2^{m}-1.

It is possible to use the H matrix in accordance with equation (2) to derive an H matrix

$${H}_{Byte} = ( \begin{matrix}{α}^{0} & {α}^{0} & {α}^{0} & … & {α}^{0} \\ {α}^{0} & {α}^{1} & {α}^{2} & … & {α}^{{2}^{m} - 2} \\ {α}^{0} & {α}^{2} & {α}^{4} & … & {α}^{2 ( {2}^{m} - 2 )}\end{matrix} ) \qquad ( 3 )$$

by multiplying the i-th column by a⁻ⁱ for i=0, . . . , (2^{m}−2). This results in only the shape of the H matrix changing, not the code, as a⁻ⁱ≠0. By way of example, this is also described in [Fujiwara, E.: Code Design for Dependable Systems, Wiley, 2006, page 65], where the value “1” is used for a⁰, as a⁰ is the unity of the Galois field used.

The following H matrix is used for a 2-byte-error-correcting and 3-byte-error-recognizing code:

$${H}_{Byte} = ( \begin{matrix}{α}^{0} & {α}^{0} & {α}^{0} & … & {α}^{0} \\ {α}^{0} & {α}^{1} & {α}^{2} & … & {α}^{{2}^{m} - 2} \\ {α}^{0} & {α}^{2} & {α}^{4} & … & {α}^{2 ( {2}^{m} - 2 )} \\ {α}^{0} & {α}^{3} & {α}^{6} & … & {α}^{3 ( {2}^{m} - 2 )} \\ {α}^{0} & {α}^{4} & {α}^{8} & … & {α}^{4 ( {2}^{m} - 2 )}\end{matrix} ) \qquad ( 4 )$$

Each column of the H matrix indicated in equation (4) corresponds to one byte.

If the length of the code is equal to N bytes or m. N bits (where each byte has m bits), only N columns of the H matrices in accordance with equation (2) or equation (4) are used. By way of example, the remaining (last) 2^{m}-2-N columns can then be deleted.

In general, the H matrix for a t-byte-error-correcting and t+1-byte-error-recognizing code can be indicated as follows:

$${H}_{Byte} = ( \begin{matrix}{α}^{0} & {α}^{0} & {α}^{0} & … & {α}^{0} \\ {α}^{0} & {α}^{1} & {α}^{2} & … & {α}^{{2}^{m} - 2} \\ {α}^{0} & {α}^{2} & {α}^{4} & … & {α}^{2 ( {2}^{m} - 2 )} \\ {α}^{0} & {α}^{3} & {α}^{6} & … & {α}^{3 ( {2}^{m} - 2 )} \\ {α}^{0} & {α}^{4} & {α}^{8} & … & {α}^{4 ( {2}^{m} - 2 )} \\ ⋮ & ⋮ & ⋮ & … & ⋮ \\ {α}^{0} & {α}^{2 t \cdot 1} & {α}^{2 t \cdot 2} & … & {α}^{2 t \cdot ( {2}^{m} - 2 )}\end{matrix} )$$

The text below considers a code, by way of illustration, that can correct2-byte errors and recognize 3-byte errors.

If an error occurs, a correct vector v=v⁰, . . . , v^{N-1} is disrupted to produce an erroneous vector v′=v^{′0}, . . . , V^{′N-1}.

The components v⁰, . . . , v^{N-1} of the vector v are bytes that each comprise m bits, so that vⁱ=vₗⁱ, . . . , vₘⁱ holds true for i=0, . . . , N−1. vⁱ, . . . , vᵢ^{m} are therefore the m bits of the i-th byte.

An m-bit byte can also be referred to as an element of the Galois field GF(2^{m}).

If there is a 1-byte error, only a single byte is erroneous, i.e. the associated i-th byte for a determined i∈{0, . . . , N−1} is erroneous.

If the correct i-th byte is denoted by vⁱ=vₗⁱ, . . . , vₘⁱ and the erroneous-th byte is denoted by v^{′i}=vₗ^{′i}, . . . , vₘ^{′i}, 1 or 2 or up to m bits of the correct i-th byte can differ from the erroneous i-th byte.

A byte error in the i-th byte can be described by
the erroneous byte position i and
a byte error value

$${e}^{i} = {v}^{i} ⊕ {v}^{′ i} = {v}_{1}^{i} ⊕ {v}_{1}^{′ i} , … , {v}_{m}^{i} ⊕ {v}_{m}^{′ i}$$

It should be noted here that“⊕” denotes the exclusive-or operation.

The position of an i-th byte can also be denoted by aⁱ.

If a byte error having the byte error value e in the byte position i is meant to be corrected, a byte error correction value that is the same as the byte error value needs to be determined for the byte position i.

In this example, the byte error value for a byte error that is to be corrected is the same as the byte error correction value; in this respect, the terms “byte error value” and “byte error correction value” can be used synonymously.

To avoid a confusing number of indices, byte error values are denoted by the letters of the alphabet a, b, c below.

A byte error correction value for the i-th byte can also be denoted by a(i).

Byte positions can be denoted by i, j, k, . . . or by aⁱ, a^{j}, a^{k}, . . . , where α is a generating element of the Galois field GF(2^{m}).

An error syndrome s has syndrome components (also referred to as components, error syndrome components, partial error syndromes or partial syndromes) s₁, s₂, s₃, s₄, s₅, which are determined for the H matrix in accordance with equation (4) as:

$$\begin{matrix}{s}_{1} = ( {α}^{0} , {α}^{0} , … , {α}^{0} ) \cdot {( {v}^{′0} , {v}^{′1} , … , {v}^{′ N - 1} )}^{T} , \\ {s}_{2} = ( {α}^{0} , {α}^{1} , … , {α}^{N - 1} ) \cdot {( {v}^{′0} , {v}^{′1} , … , {v}^{′ N - 1} )}^{T} , \\ {s}_{3} = ( {α}^{0} , {α}^{2} , … , {α}^{2 ( N - 1 )} ) \cdot {( {v}^{′0} , {v}^{′1} , … , {v}^{′ N - 1} )}^{T} , \\ {s}_{4} = ( {α}^{0} , {α}^{3} , … , {α}^{3 ( N - 1 )} ) \cdot {( {v}^{′0} , {v}^{′1} , … , {v}^{′ N - 1} )}^{T} , \\ {s}_{5} = ( {α}^{0} , {α}^{4} , … , {α}^{4 ( N - 1 )} ) \cdot {( {v}^{′0} , {v}^{′1} , … , {v}^{′ N - 1} )}^{T} .\end{matrix}$$

In this case, v^{′0}, . . . ,v^{′N-1})^{T} is a column vector having the components v^{′0}, . . . ,v^{′N-1}), which can also be referred to as a transpose vector of the row vector v^{′0}, . . . ,v^{′N-1}).

The syndrome components s₁, s₂, s₃, s₄, s₅ each form a byte having m bits.

If there is no error, it holds true that:

$${s}_{1} = {s}_{2} = {s}_{3} = {s}_{4} = {s}_{5} = 0 .$$

If there is a 1-byte error having the byte error value a in the i-th byte error position, it holds true that:

$${s}_{1} = {α}^{0} \cdot a = a \qquad ( 5 )$$

$${s}_{2} = {α}^{i} \cdot a$$

$${s}_{3} = {α}^{2 i} \cdot a$$

$${s}_{4} = {α}^{3 i} \cdot a$$

$${s}_{5} = {α}^{4 i} \cdot a .$$

If there is a 2-byte error having the byte error values a and b in the byte error positions i and j, it holds true that:

$${s}_{1} = {α}^{0} a + {α}^{0} b = a + b \qquad ( 6 )$$

$${s}_{1} = {α}^{i} \cdot a + {α}^{j} \cdot b$$

$${s}_{3} = {α}^{2 i} \cdot a + {α}^{2 j} \cdot b$$

$${s}_{4} = {α}^{3 i} \cdot a + {α}^{3 j} \cdot b$$

$${s}_{5} = {α}^{4 i} \cdot a + {α}^{4 j} \cdot b .$$

If there is a 3-byte error having the byte error values a, b and c in the byte error positions i, j and k, it holds true that:

$${s}_{1} = {α}^{0} a + {α}^{0} b + {α}^{0} c = a + b + c \qquad ( 7 )$$

$${s}_{2} = {α}^{i} \cdot a + {α}^{j} \cdot b + {α}^{k} \cdot c$$

$${s}_{3} = {α}^{2 i} \cdot a + {α}^{2 j} \cdot b + {α}^{2 k} \cdot c$$

$${s}_{4} = {α}^{3 i} \cdot a + {α}^{3 j} \cdot b + {α}^{3 k} \cdot c$$

$${s}_{5} = {α}^{4 i} \cdot a + {α}^{4 j} \cdot b + {α}^{4 k} \cdot c .$$

### Correction of 3-Byte Errors

One option is to transform k-bit bytes that form bytes of a codeword of a first error code, e.g. a Reed-Solomon code, into n-bit bytes that form codewords of a second error code. In this regard, reference is also made to U.S. Pat. No. 10,903,859 B2. By way of example, a Reed-Solomon code can be used in which data bytes have check bytes added to form a codeword.

By way of example, the second error code is an r-out-of-n code containing r ones and n-r zeros. The codeword comprises n bits.

The second error code can also comprise an r₁-out-of-n, r₂-out-of-n to r_{q}-out-of-n code containing r₁ ones and n-r₁ zeros, r₂ ones and n-r₂ zeros to r_{q} ones and n-r_{q} zeros. The codeword has n bits in this example too.

If there is no error, it holds true that: k-bit bytes of the first error code are reversibly uniquely transformed into n-bit bytes of the second error code, which are each stored in n memory cells. After the n memory cells are read, the read n-bit codewords of the second error code are transformed back into their respective corresponding k-bit bytes.

If there is an error, e.g. a read error, a word that is not a codeword (also referred to as a non-codeword) of the second error code is read from the n memory cells. The non-codeword can therefore be used to detect that an error has occurred. Back-transformation of this non-codeword into a k-bit byte can lead to an erroneous k-bit byte of the first error code.

It is thus possible to identify that an error has occurred in an i-th byte of the first error code if no codeword of the second error code has been read from the n memory cells. It is therefore possible to determine that the i-th byte position is erroneous. This i-th byte position is also referred to as an erasure (byte error position). For the i-th byte position of the first error code, a byte error position signal BPsᵢ can indicate whether the i-th byte of the first error code is erroneous. By way of example, it holds true that:
BPsᵢ=1: the i-th byte of the first error code is erroneous.
BPsᵢ=0: no error in the i-th byte has been identified.

Here, i can assume the values 0, 1, . . . , M−1; in this case the codeword of the first error code comprises M bytes.

If the first error code is for example a Reed-Solomon code over the Galois field GF(2^{m}), the byte position i may have a reversibly uniquely associated value aⁱ, a being a generating element of the Galois field.

In general, a byte error position signal can therefore be determined that assumes a first value when an n-bit codeword of the second error code has occurred and assumes a second value when a non-codeword of the second error code has occurred. By way of illustration, the byte error position signal equal to 1 for a byte position i is intended here to indicate that there is an error in the k-bit byte of the Reed-Solomon code in the applicable byte position. The value 1 of the byte error position signal then indicates a byte error position (an erasure) in the byte position i.

The k-bit bytes can form bytes of a codeword of a byte error code, for example a Reed-Solomon code over the Galois field GF(2^{m}) where m≥2. Correction of an erroneous k-bit byte on the basis of the Reed-Solomon code requires the erroneous byte position (byte error position) and the byte error value.

In accordance with the example explained here, the erroneous byte position is already determined by the value of the byte error position signal. If the value of the byte error position signal BP_{Sk} has been determined to be 1, it follows that the k-bit byte into which the applicable non-codeword of the second error code is transformed back is erroneous. It is then not necessary to determine the erroneous position of the k-bit byte using the check bytes or the syndrome components of the Reed-Solomon code, as the position is already known. Check bytes can therefore be saved.

If there is a byte error for which the byte error position is known, only one check byte of the Reed-Solomon code is required for correction. If there are two byte errors for which both byte error positions are known, only two check bytes of the Reed-Solomon code are required for correcting the two byte errors. If there are three byte errors for which all three byte error positions are known, only three check bytes of the Reed-Solomon code are required for the correction.

In general, it holds true that: if M error-free k-bit bytes B₀, B₁, . . . , B_{M-1} having the byte positions 0, 1, 2, . . . , M−1 form a codeword of the Reed-Solomon code, the byte positions may have the reversibly uniquely associated elements a⁰, a¹, . . . , a^{M-1} of the Galois field GF(2^{m}). A byte error can then be described by the byte error position i, or equivalently by aⁱ, and a byte error value v(i). The byte error value v(i) is a k-bit byte.

If the byte error position signal is BPs_{L}=0, no error in the L-th byte is corrected. This situation can also be described as a result of the L-th byte, for which a byte error value v(L) has been determined, also being corrected to give BPs_{I}·v(L)=0, and so no correction is performed on account of multiplication by 0.

If the byte error position signal is BPs_{L}=1, then the L-th byte BL is erroneous and a corrected value BPs_{I}·v(L)=v(L) is not equal to 0.

As an example, a Reed-Solomon code having three check bytes and accordingly having three syndrome components s₁, s₂, s₃ will be considered below.

If there is a 3-byte error in the byte error positions i,j,k or aⁱ, a^{j}, a^{k} with the byte error values

$$v ( i ) = a ,$$

$$v ( j ) = b ,$$

$$v ( k ) = c$$

then it holds true that

$${s}_{1} = a + b + c , \qquad ( 8 )$$

$${s}_{2} = {α}^{i} a + {α}^{j} b + {α}^{k} c , \qquad ( 9 )$$

$${s}_{3} = {α}^{2 i} a + {α}^{2 j} b + {α}^{2 k} c . \qquad ( 11 )$$

The addition and multiplication operations used should be interpreted as operations in the Galois field GF(2^{m}).

In particular, it is proposed that a k-bit-wide value A, a k-bit-wide value B and a k-bit-wide value C be determined once, as follows:

$$A = \frac{{s}_{1} {S}_{1}^{2} + {s}_{3}}{{S}_{1}^{3} + {S}_{3}} , \qquad ( 11 )$$

$$B = {s}_{1} + \frac{{s}_{2} {S}_{1}^{2} + {s}_{2} {S}_{1}}{{S}_{1}^{3} + {S}_{3}} , \qquad ( 12 )$$

$$C = \frac{{s}_{1} {S}_{1} + {s}_{2}}{{S}_{1}^{3} + {S}_{3}} . \qquad ( 13 )$$

These values A, B, C are also referred to as correction values. They are determined on the basis of the three syndrome components s₁, s₂ and s₃ and symmetrical functions

$${S}_{1} = {α}^{i} + {α}^{j} + {α}^{k} , \qquad ( 14 )$$

$${S}_{2} = {S}_{1}^{2} = {α}^{2 i} + {α}^{2 j} + {α}^{2 k} , \qquad ( 15 )$$

$${S}_{3} = {α}^{3 i} + {α}^{3 j} + {α}^{3 k} \qquad ( 16 )$$

of the powers of aⁱ, a^{j}, a^{k}.

For each byte position L, which can also be indicated as aⁱ, a possible byte error value v(L) is determined from the correction values A, B, C and the respective byte position a^{L} as:

$$v ( L ) = {α}^{L} \cdot A + B + {α}^{2 L} \cdot C . \qquad ( 17 )$$

Each of the byte positions considered is provided with the first value A, which is the same for the different byte positions, on a first m-bit-wide line, with the second value B, which is the same for the different byte positions, on an m-bit-wide line, and with the third value C, which is the same for the different byte positions, likewise on an m-bit-wide line.

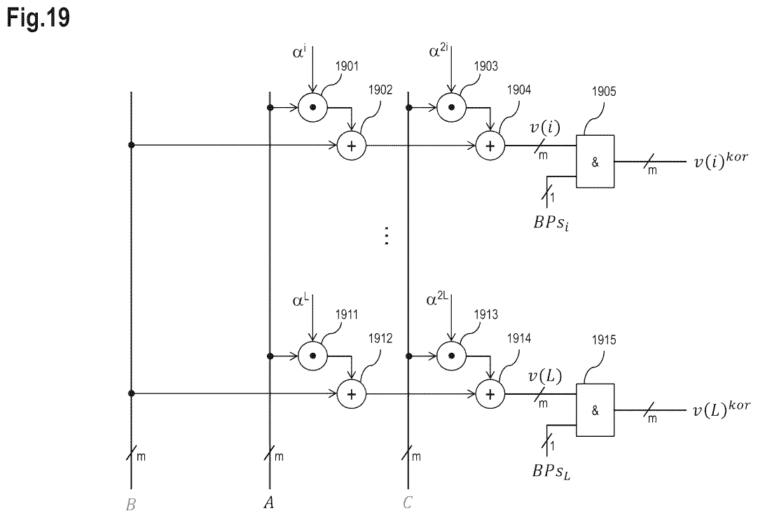

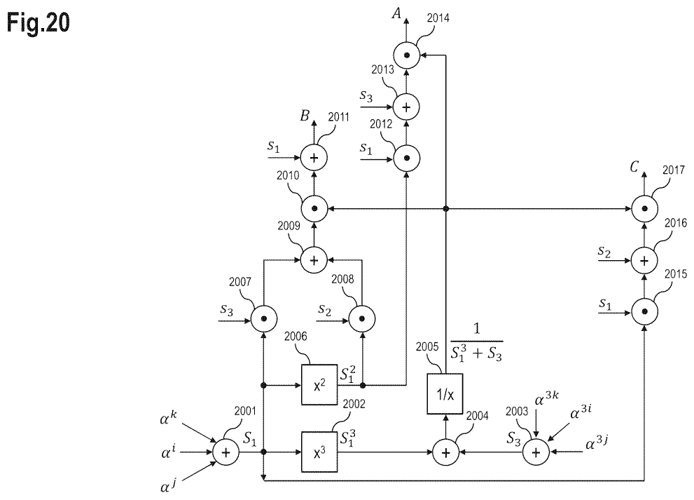

FIG. 19 shows an illustrative parallel implementation for correcting a byte error value v(i) at the byte error position i and a byte error value v(L) at the byte error position L by using byte error position signals BPsᵢ and BPs_{L}. The correction values A, B and C in accordance with equation (17) are used in this instance.

By way of illustration, the generation of a corrected signal v(i)^{kor} is described. This is accomplished using adders 1902, 1904, multipliers 1901, 1903 and an AND gate 1905. Each adder is an adder in the Galois field GF(2^{m}) and corresponds to a component-by-component XOR function. The AND gate 1905 delivers v(i)^{kor}=0 at its output when BPsᵢ=0, otherwise (that is to say if BPsᵢ=1) v(i)^{kor}=v(i) is provided at the output.

The correction value A is multiplied by the constant a^{L} using the multiplier 1901 and added to the correction value B using the adder 1902.

The correction value C is multiplied by the constant a²i using the multiplier 1903 and added together with the result of the adder 1902 in the adder 1904 to give the byte error value v(i) and routed to the m-bit-wide input of the AND gate 1905. The AND gate 1905 also has a 1-bit-wide input that is connected to the byte error position signal BPsᵢ. The m-bit-wide corrected signal v(i)^{kor} is provided at the output of the AND gate 1905.

In parallel with this, the corrected signal v(L) kor for the L-th byte position can be determined. This is accomplished using appropriate components, here adders 1912, 1914, multipliers 1911, 1913, an AND gate 1915 in combination with a byte error position signal BPs_{L}.

FIG. 20 shows an illustrative implementation for providing the correction values A, B and C. This is accomplished using adders 2001, 2003, 2004, 2009, 2011, 2013, 2016, multipliers 2007, 2008, 2010, 2012, 2014, 2015, 2017, a squarer 2006, a cuber 2002 and an inverter 2005. The lines shown are m bits wide. Each adder is an adder in the Galois field GF(2^{m}) and performs a component-by-component XOR function. Each multiplier is a multiplier in the Galois field GF(2^{m}). The inverter 2005 is a Galois field GF(2^{m}) inverter.

The adder 2001 is used to form the symmetrical function S₁ from the elements of the Galois field aⁱ, a^{j}, a^{k} in accordance with equation (14). The cuber 2002 determines the value s₁³ therefrom and relays it to the adder 2004.

The adder 2003 is used to form the symmetrical function s₃ from the elements of the Galois field a³ⁱi, α3^{j}, α3^{k} in accordance with equation (16), the symmetrical function being added to S₁³ in the adder 2004.

The output of the adder 2004 is connected to the input of the inverter 2005. The term

$$\frac{1}{{S}_{1}^{3} + {S}_{3}}$$

is therefore provided at the output of the inverter 2005.

The correction value B is determined as follows: the output of the adder 2001 is connected to the input of the squarer 2006 and to the input of the multiplier 2007. The other input of the multiplier 2007 is connected to the syndrome component s₃ and the output of the multiplier 2007 is connected to the input of the adder 2009. The output of the squarer 2006 provides S₁² and is connected to the input of the multiplier 2008. The syndrome component s₂ is provided at the other input of the multiplier 2008. The outputs of the adders 2007 and 2008 are connected to different inputs of the adder 2009. The term

$${S}_{1} {s}_{3} + {S}_{1}^{2} {s}_{2}$$

is therefore provided at the output of the adder 2009. The output of the adder 2009 is connected to the input of the multiplier 2010, and the other input of the multiplier 2010 is connected to the output of the inverter 2005. The output of the multiplier 2010 is connected to the input of the adder 2011, the other input of which has the syndrome component s₁ applied to it. The correction value

$$B = {s}_{1} + \frac{{s}_{2} {S}_{1}^{2} + {s}_{3} {S}_{1}}{{S}_{1}^{3} + {S}_{3}}$$

in accordance with equation (12) is therefore provided at the output of the adder 2011.

The correction value A is determined as follows: the output of the squarer 2006 is connected to the input of the multiplier 2012, the other input of which is connected to the syndrome component s₁. The output of the multiplier 2012 is connected to the input of the adder 2013, the other input of which is provided with the syndrome component s₃. The output of the adder 2013 is connected to the input of the multiplier 2014. The other input of the multiplier 2014 is connected to the output of the inverter 2005. The output of the multiplier 2014 therefore has the correction value

$$A = \frac{{s}_{1} {S}_{1}^{2} + {s}_{3}}{{S}_{1}^{3} + {S}_{3}}$$

in accordance with equation (11) applied to it.

The correction value C is determined as follows: the output of the adder 2001 is connected to the input of the multiplier 2015, the other input of which is connected to the syndrome component s₁. The output of the multiplier 2015 is connected to the input of the adder 2016, the other input of which is provided with the syndrome component s₂. The output of the adder 2016 is connected to the input of the multiplier 2017. The other input of the multiplier 2017 is connected to the output of the inverter 2005. The output of the multiplier 2017 therefore has the correction value

$$C = \frac{{s}_{1} {S}_{1} + {s}_{2}}{{S}_{1}^{3} + {S}_{3}}$$

in accordance with equation (13) applied to it.

In some examples, elements 1901, 1902, 1903, 1904, 1905, 1911, 1912, 1913, 1914, 1915, 2001, 2002, 2003, 2004, 2005, 2006, 2007, 2008, 2009, 2010, 2011, 2012, 2013, 2014, 2015, 2016, and 2017 can be implemented as logic circuits a single standalone chip or a single die, but in other examples elements 1901, 1902, 1903, 1904, 1905, 1911, 1912, 1913, 1914, 1915, 2001, 2002, 2003, 2004, 2005, 2006, 2007, 2008, 2009, 2010, 2011, 2012, 2013, 2014, 2015, 2016, and 2017 are on multiple dies stacked over one another or arranged within a single integrated circuit package in the form of a so-called 3-dimensional IC. In still other examples, elements 1901, 1902, 1903, 1904, 1905, 1911, 1912, 1913, 1914, 1915, 2001, 2002, 2003, 2004, 2005, 2006, 2007, 2008, 2009, 2010, 2011, 2012, 2013, 2014, 2015, 2016, and 2017 may be formed on multiple packaged chips and/or discrete components on a printed circuit board (PCB). Elements 1901, 1902, 1903, 1904, 1905, 1911, 1912, 1913, 1914, 1915, 2001, 2002, 2003, 2004, 2005, 2006, 2007, 2008, 2009, 2010, 2011, 2012, 2013, 2014, 2015, 2016, and 2017 can thus be coupled by wires or buses, such as metal traces on a PCB and/or metallization interconnect layers of an integrated circuit die(s). A die may include a semiconductor substrate, such as a monocrystalline silicon substrate or a silicon on insulator substrate, but can also and/or alternatively include other semiconductor materials, such as gallium arsenide (GaAs), indium gallium arsenide (InGaAs), and germanium (Ge), among others. Further, the chip(s) can include transistors arranged in an application specific integrated circuit (ASIC) to specifically carry out the functions of the elements 1901, 1902, 1903, 1904, 1905, 1911, 1912, 1913, 1914, 1915, 2001, 2002, 2003, 2004, 2005, 2006, 2007, 2008, 2009, 2010, 2011, 2012, 2013, 2014, 2015, 2016, and 2017; and/or can be implemented using software or firmware instructions to carry out functions using a processor and memory. The memory can be read only memory (ROM), one-time programmable memory (e.g., fuses), or other non-volatile memory that stores the instructions in some examples. In some cases (e.g., ROM and fuses), the structural patterns present in the memory represent the bits of the executable instructions and differ from structural patterns of other memories that have other executable instructions. The same is true for other elements, blocks, circuits, and the like illustrated herein.

As indicated in equation (17), for each considered byte position L where L=0, . . . , M−1,
the correction value A is multiplied by the first constant a^{L} corresponding to the L-th byte position,
the correction value C is multiplied by the second constant a^{2L} corresponding to the L-th byte position.

The correction value B, the correction value A multiplied by a^{L} and the correction value C multiplied by a^{2L} are added, the addition taking place in the Galois field GF(2^{m}). If the values to be added in GF(2^{m}) are represented as m-component binary vectors in their vector representation, then the addition in the Galois field GF(2^{m}) has a corresponding component-by-component addition modulo 2, or component-by-component Exclusive-Or function (XOR function).

For the three byte positions i,j,k in which an erroneous byte has occurred, it holds true for the byte error position signals that

$${BPs}_{i} = {BPs}_{j} = {BPs}_{k} = 1$$

and a correction is performed in these byte positions. For all the other byte positions, in which no error has occurred, the byte error position signals are equal to 0 and no correction is performed there.

Inserting equations (8), (9), (10), (14) and (16) into equation (17) yields the following for the erroneous byte error positions i,j,k that are to be corrected:

$$v ( i ) = a , v ( j ) = b , v ( k ) = c . \qquad ( 18 )$$

Here,

$${BFs}_{L} = \{ \begin{matrix}1 & for L = i , j , k \\ 0 & otherwise\end{matrix} \qquad ( 19 )$$

the value

BPs_{L}·v(L)

determined for a byte position L with BPs_{L}=0 in which no error has occurred is 0·v(L)=0, irrespective of the value of v(L), and no correction is then performed.

In equations (11), (12) and (13), S₁ in accordance with equation (14) is determined as

$${S}_{1} = {α}^{i} + {α}^{i} + {α}^{k} .$$

S₁ is a coefficient of the locator polynomial L₃(x) and is a symmetrical function.

If the locator polynomial is used in the form

$$\begin{matrix}{L}_{3} ( x ) & = ( x + {α}^{i} ) ( x + {α}^{j} ) ( x + {α}^{k} ) = \\ & = {x}^{3} + {x}^{2} ( {α}^{i} + {α}^{j} + {α}^{k} ) + x ( {α}^{i} {α}^{j} + {α}^{i} {α}^{k} + {α}^{j} {α}^{k} ) + {α}^{i} {α}^{j} {α}^{k}\end{matrix}$$

then S₁ is the coefficient of x².

S₁ is a symmetrical function in aⁱ, a^{j}, a^{k} and, in accordance with equation several lines above, the sum of powers of the first powers of aⁱ, a^{j}, a^{k} in the Galois field under consideration. If aⁱ, a^{j}, a^{k} are used as binary vectors in their vector representation, this sum can be implemented as a component-by-component XOR function.

If the locator polynomial is used in the form

$$\begin{matrix}{L}_{3} {( x )}^{′} & = ( 1 + {α}^{j} x ) ( 1 + {α}^{j} x ) ( 1 + {α}^{k} x ) = \\ & = 1 + x ( {α}^{i} + {α}^{j} + {α}^{k} ) + {x}^{2} ( {α}^{i} {α}^{j} + {α}^{i} {α}^{k} + {α}^{j} {α}^{k} ) + {α}^{i} {α}^{j} {α}^{k}\end{matrix}$$

then S₁ is the coefficient of x.

### Derivation of the Correction

The text below shows how equation (17) can be determined.

A Reed-Solomon code comprising an H matrix

$$H = ( \begin{matrix}{α}^{0} & {α}^{0} & {α}^{0} & … \\ {α}^{0} & {α}^{1} & {α}^{2} & … \\ {α}^{0} & {α}^{2} & {α}^{4} & …\end{matrix} ) . \qquad ( 20 )$$

is provided. It is assumed that there is a 3-byte error in the byte error positions aⁱ, a^{j}, a^{k} having the byte error values

$$v ( i ) = a ,$$

$$v ( j ) = b ,$$

$$v ( k ) = c$$

the byte error positions aⁱ, a^{j}, a^{k} being known and the byte error values a, b and c not being known. The byte error values a, b, c are intended to be determined. A 3-byte error can be corrected even if only three syndrome components s₁, s₂, and ss are determined.

The unknown byte error value c=v(k) for the known byte error position a^{k} can be determined by modifying the error syndrome of the 3-byte error in the positions aⁱ, a^{j}, a^{k} with an assumed byte error value c that is to be determined and with known a^{k} to produce a syndrome of a 2-byte error in the byte error positions aⁱ, a^{j} with the byte error values a=v(i) and b=v(j).

As a result, an equation for the byte error value c is derived that permits the byte error value c to be determined from the byte error positions aⁱ, a^{j}, a^{k} and the syndrome components s₁, s₂, s₃.

An approach to a solution can be summarized as follows:

The syndrome component

$${s}_{1} = a + b + c$$

of the 3-byte error with three byte error positions is converted into a syndrome component

$${s}_{1}^{′} = {s}_{1} + c = a + b .$$

The syndrome component

$${s}_{2} = {α}^{i} a + {α}^{j} b + {α}^{k} c$$

of the 3-byte error with three byte error positions is converted into a syndrome component

$${s}_{2}^{′} = {s}_{2} + {α}^{k} c = {α}^{i} a + {α}^{j} b .$$

The syndrome component

$${s}_{3} = {α}^{2 i} a + {α}^{2 j} b + {α}^{2 k} c$$

of the 3-byte error with three byte error positions is converted into a syndrome component

$${s}_{3}^{′} = {s}_{3} + {α}^{k} c = {α}^{2 i} a + {α}^{2 j} b .$$

The converted syndrome components s′₁, s′2, s's are syndrome components of a 2-byte error.

For a 2-byte error with the components of the error syndrome s′₁, s′₂, s′₃ and the coefficients σ′₁ and σ′₂ of the locator polynomial of the Reed-Solomon code with

$${σ}_{1}^{′} = {α}^{i} + {α}^{j} ,$$

$${σ}_{2}^{′} = {α}^{i} \cdot {α}^{j}$$

and with

$${s}_{1}^{′} = a + b ,$$

$${s}_{2}^{′} = {α}^{i} \cdot a + {α}^{j} \cdot b ,$$

$${s}_{3}^{′} = {α}^{2 i} \cdot a + {α}^{2 j} \cdot b$$

it holds true that

$${s}_{1}^{′} \cdot {σ}_{2}^{′} + {s}_{2}^{′} \cdot {σ}_{1}^{′} = {s}_{3}^{′} . \qquad ( 21 )$$

Equations (8) to (10) yield:

$${s}_{1}^{′} = {s}_{1} + c , \qquad ( 22 )$$

$${s}_{2}^{′} = {s}_{2} + {α}^{k} \cdot c , \qquad ( 23 )$$

$${s}_{3}^{′} = {s}_{3} + {α}^{2 k} \cdot c . \qquad ( 24 )$$

As the byte error positions aⁱ, a^{j}, a^{k} are known, the byte error value c can be determined in such a way that equation (21) is satisfied when s′₁, s′₂ and s'₃ are determined according to equations (22) to (24) from s₁, s₂, s₃ and c. It holds true that:

$$( {s }_{1} + c ) ( {α}^{i} {α}^{j} ) + ( {s}_{2} + {α}^{k} c ) ( {α}^{i} + {α}^{j} ) = {s}_{3} + {a}^{2 k} c . \qquad ( 25 )$$

Transformation yields:

$${s}_{1} {α}^{i} {α}^{j} + {s}_{2} ( {a}^{i} + {a}^{j} ) + {s}_{3} = c [ {α}^{i} {α}^{j} + {a}^{i} {a}^{k} + {α}^{j} {α}^{k} + {α}^{2 k} ] .$$

Furthermore, it holds true that:

$$v ( k ) = c = \frac{{s}_{1} {α}^{i} {α}^{j} + {s}_{2} ( {α}^{i} + {α}^{j} ) + {s}_{3}}{{α}^{i} {α}^{j} + {α}^{i} {α}^{k} + {α}^{j} {α}^{k} + {α}^{2 k}} = \frac{Z}{N} . \qquad ( 26 )$$

It holds true for the denominator N that

$$N = {α}^{i} {α}^{j} + {α}^{i} {α}^{k} + {α}^{j} {α}^{k} + {α}^{2 k} = ( {α}^{i} + {α}^{k} ) ( {α}^{j} + {α}^{k} ) .$$

As aⁱ, a^{j}, a^{k} are different in pairs, the denominator Nin equation (26) is always not equal to 0. The resolution according to c is therefore always possible. Equation (26) is also representable in the form

$$v ( k ) = c = \frac{{s}_{1} {α}^{i} {α}^{j} + {s}_{2} ( {α}^{i} + {α}^{j} ) + {s}_{3}}{( {α}^{i} + {α}^{k} ) ( {α}^{j} + {α}^{k} )} \qquad ( 27 )$$

Accordingly, it holds true for the byte error correction values a and b of the byte error positions aⁱ and a^{j} that

$$v ( i ) = a = \frac{{s}_{1} {α}^{j} {α}^{k} + {s}_{2} ( {α}^{j} + {α}^{k} ) + {s}_{3}}{( {α}^{j} + {α}^{i} ) ( {α}^{k} + {α}^{i} )} \\ and \qquad ( 28 )$$

$$v ( j ) = b = \frac{{s}_{1} {α}^{i} {α}^{k} + {s}_{2} ( {α}^{i} + {α}^{k} ) + {s}_{3}}{( {α}^{i} + {α}^{j} ) ( {α}^{k} + {α}^{j} )} . \qquad ( 29 )$$

Hitherto, c=v(k) has been determined by equation (26), or equation (27), from s₁, s₂, s₃ and aⁱ, a^{j} and a^{k}.

The text below explains how a parallelizable solution can be achieved for the byte positions that are to be corrected.

The denominator N is modified as follows:

$$N = ( {α}^{i} + {α}^{k} ) ( {α}^{j} + {α}^{k} ) = ( {α}^{i} + {α}^{k} ) + ( {α}^{j} + {α}^{k} ) \frac{( {α}^{i} + {α}^{j} )}{( {α}^{i} + {α}^{j} )} = \frac{{N}_{1}}{{N}_{2}} . \\ with {N}_{1} = ( {α}^{i} + {α}^{k} ) ( {α}^{j} + {α}^{k} ) ( {α}^{i} + {α}^{j} ) . \qquad ( 30 )$$

N₁ is a symmetrical function in aⁱ, a^{j}, a^{k}. The symmetrical functions S₁ and s₃ in accordance with equation (14) and equation (16) can be used to transform N₁ into

$${N}_{1} = {( {S}_{1} )}^{3} + {S}_{3} . \qquad ( 31 )$$

Here, s₃ is the sum of powers of the third powers a³ⁱ, a^{3j}, a^{3k} of aⁱ, a^{j}, a^{k}.

Equation (31) can be verified by recalculation. The symmetrical functions St and Ss can be determined from the byte error positions aⁱ, a^{j}, a^{k}.

Multiplying out M from equation (30) thus yields:

$$\begin{matrix}{N}_{1} = ( {α}^{i} + {α}^{k} ) ( {α}^{j} + {α}^{k} ) ( {α}^{i} + {α}^{j} ) = \\ = ( {α}^{i} {α}^{j} + {α}^{i} {α}^{k} + {α}^{j} {α}^{k} + {α}^{2 k} ) ( {α}^{i} + {α}^{j} ) = \\ = {α}^{2 i} {α}^{j} + {α}^{i} {α}^{2 j} + {α}^{2 i} {α}^{k} + {α}^{i} {α}^{j} {α}^{k} + {α}^{i} {α}^{j} {α}^{k} + {α}^{2 j} {α}^{k} + {α}^{i} {α}^{2 k} + {a}^{j} {α}^{2 k} = \\ = {α}^{2 i} {α}^{j} + {α}^{2 i} {α}^{k} + {α}^{i} {α}^{2 j} + {α}^{2 j} {α}^{k} + {α}^{i} {α}^{2 k} + {α}^{j} {α}^{2 k} = \\ = {α}^{2 i} ( {α}^{j} + {α}^{k} ) + {α}^{2 j} ( {α}^{i} + {α}^{k} ) + {α}^{2 k} ( {α}^{i} + {α}^{j} )\end{matrix}$$

On the other hand, equations (14) and (16), when inserted into equation (31), yield:

$$\begin{matrix}{( {S}_{1} )}^{3} + {S}_{3} = {( {α}^{i} + {α}^{j} + {α}^{k} )}^{3} + {α}^{3 i} + {α}^{3 j} + {α}^{3 k} = \\ = {( {α}^{i} + {α}^{j} + {α}^{k} )}^{2} ( {α}^{i} + {α}^{j} + {α}^{k} ) + {α}^{3 i} + {α}^{3 j} + {α}^{3 k} = \\ = ( {α}^{2 i} + {α}^{i} {α}^{j} + {α}^{i} {α}^{k} + {α}^{i} {α}^{j} + {α}^{2 j} + {α}^{j} {α}^{k} + {a}^{i} {α}^{k} + {a}^{j} {α}^{k} + {α}^{2 k} ) \cdot \cdot \\ ( {α}^{i} + {α}^{j} + {α}^{k} ) + {α}^{3 i} + {α}^{3 j} + {α}^{3 k} = \\ = ( {α}^{2 i} + {α}^{2 j} + {α}^{2 k} ) ( {α}^{i} + {α}^{j} + {α}^{k} ) + {α}^{3 i} + {α}^{3 j} + {α}^{3 k} = \\ = {α}^{3 i} + {α}^{2 i} {α}^{j} + {α}^{2 i} {α}^{k} + {α}^{2 j} {α}^{i} + {α}^{3 j} + {α}^{2 j} {α}^{k} + {a}^{i} {α}^{2 k} + {α}^{j} {α}^{2 k} + {α}^{3 k} ++ \\ {α}^{3 i} + {α}^{3 j} + {α}^{3 k} = \\ = {α}^{2 i} {α}^{j} + {α}^{2 i} {α}^{k} + {α}^{2 j} {α}^{i} + {α}^{2 j} {α}^{k} + {a}^{i} {α}^{2 k} + {α}^{j} {α}^{2 k} = \\ = {α}^{2 i} ( {α}^{j} + {α}^{k} ) + {α}^{2 j} ( {α}^{i} + {α}^{k} ) + {α}^{2 k} ( {α}^{i} + {α}^{j} ) = \\ = {N}_{1}\end{matrix}$$

The following is thus obtained for c=v(k) based on equations (27), (30) and (31):

$$v ( k ) = c = \frac{[ {s}_{1} {α}^{i} {α}^{j} + {s}_{2} ( {α}^{i} + {α}^{j} ) + {s}_{3} ] \cdot [ {α}^{i} + {α}^{j} ]}{{S}_{1}^{3} + {S}_{3}} \qquad ( 32 )$$

Equation (14) yields

$${α}^{i} + {α}^{j} = {S}_{1} + {α}^{k} . \qquad ( 33 )$$

Since it holds true that

$$\begin{matrix}{( {α}^{i} + {α}^{j} )}^{3} + {α}^{3 i} + {α}^{3 j} = {( {α}^{i} + {α}^{j} )}^{2} ( {α}^{i} + {α}^{j} ) + {α}^{3 i} + {α}^{3 j} = \\ = ( {α}^{2 i} + {α}^{2 j} ) ( {α}^{i} + {α}^{j} ) + {α}^{3 i} + {α}^{3 j} = \\ = {α}^{3 i} + {α}^{2 i} {α}^{j} + {α}^{i} {α}^{2 j} + {α}^{3 j} + {α}^{3 i} + {α}^{3 j} = \\ = {α}^{2 i} {α}^{j} + {α}^{i} {α}^{2 j}\end{matrix} \\ and \\ {α}^{i} {α}^{j} ( {α}^{i} + {α}^{j} ) = {α}^{2 i} {α}^{j} + {α}^{i} {α}^{2 j}$$

it follows that

$${α}^{j} {α}^{j} ( {α}^{i} + {α}^{j} ) = {( {α}^{i} - {α}^{j} )}^{3} + {α}^{3 i} + {α}^{3 j} \qquad ( 34 )$$

Equation (16) yields

$${α}^{3 i} + {α}^{3 j} = {S}_{3} + {α}^{3 k} . \qquad ( 35 )$$

When equations (33) and (35) are inserted into equation (34), it follows that:

$$\begin{matrix}{α}^{j} {α}^{j} ( {α}^{i} + {α}^{j} ) = {( {S}_{1} + {α}^{k} )}^{3} + {S}_{3} + {α}^{3 k} = \\ = {( {S}_{1} + {α}^{k} )}^{2} ( {S}_{1} + {α}^{k} ) + {S}_{3} + {α}^{3 k} = \\ = {( {S}_{1}^{2} + {α}^{2 k} )}^{} ( {S}_{1} + {α}^{k} ) + {S}_{3} + {α}^{3 k} = \\ = {S}_{1}^{3} + {S}_{1}^{2} {α}^{k} + {S}_{1} {α}^{2 k} + {α}^{3 k} + {S}_{3} + {α}^{3 k} = \\ = {S}_{1}^{3} + {S}_{3} + {S}_{1} {α}^{2 k} + {S}_{1}^{2} {α}^{k}\end{matrix} \qquad ( 36 )$$

Equation (32) yields

$$\begin{matrix}v ( k ) = c = \frac{[ {s}_{1} {α}^{i} {α}^{j} + {s}_{2} ( {α}^{i} + {α}^{j} ) + {s}_{3} ] \cdot ( {α}^{i} + {α}^{j} )}{{S}_{1}^{3} + {S}_{3}} = \\ = \frac{{s}_{1} {α}^{i} {α}^{j} ( {α}^{i} + {α}^{j} ) + {{s}_{2} ( {α}^{i} + {α}^{j} )}^{2} + {s}_{3} ( {α}^{i} + {α}^{j} )}{{S}_{1}^{3} + {S}_{3}}\end{matrix} \qquad ( 37 )$$

Equation (36), equation (33) and

$${( {α}^{j} + {α}^{j} )}^{2} = {( {S}_{1} + {α}^{k} )}^{2} = {S}_{1}^{2} + {α}^{2 k} \qquad ( 38 )$$

yield

$$( 39 )$$

$$\begin{matrix}v ( k ) = c = \frac{{s}_{1} ( {S}_{1}^{3} + {S}_{3} + {S}_{1} {α}^{2 k} + {S}_{1}^{2} {α}^{k} ) + {s}_{2} ( {S}_{1}^{2} + {α}^{2 k} ) + {s}_{3} ( {S}_{1} + {α}^{k} )}{{S}_{1}^{3} + {S}_{3}} = \\ = \frac{{s}_{1} ( {S}_{1}^{3} + {S}_{3} ) + {s}_{1} {S}_{1} {α}^{2 k} + {s}_{1} {S}_{1}^{2} {α}^{k} + {s}_{2} {S}_{1}^{2} + {s}_{2} {α}^{2 k} + {s}_{3} {S}_{1} + {s}_{3} {α}^{k} )}{{S}_{1}^{3} + {S}_{3}} = \\ = {s}_{1} + \frac{{s}_{1} {S}_{1} {α}^{2 k} + {s}_{1} {S}_{1}^{2} {α}^{k} + {s}_{2} {S}_{1}^{2} + {s}_{2} {α}^{2 k} + {s}_{3} {S}_{1} + {s}_{3} {α}^{k}}{{S}_{1}^{3} + {S}_{3}} = \\ = {α}^{k} \cdot [ \frac{{s}_{1} {S}_{1}^{2} + {s}_{3}}{{S}_{1}^{3} + {S}_{3}} ] + {s}_{1} + \frac{{s}_{2} {S}_{1}^{2} + {s}_{3} {S}_{1}}{{S}_{1}^{3} + {S}_{3}} + {α}^{2 k} \cdot [ \frac{{s}_{1} {S}_{1} + {s}_{2}}{{S}_{1}^{3} + {S}_{3}} ]\end{matrix}$$

It is therefore sufficient to form

$$\frac{{s}_{1} {S}_{1}^{2} + {s}_{3}}{{S}_{1}^{3} + {S}_{3}} = A ,$$

$${s}_{1} + \frac{{s}_{2} {S}_{1}^{2} + {s}_{3} {S}_{1}}{{S}_{1}^{3} + {S}_{3}} = B$$

$$and$$

$$\frac{{s}_{1} {S}_{1} + {s}_{2}}{{S}_{1}^{3} + {S}_{3}} = C$$

only once. The multiplications by a^{k} and a^{2k} in the k-th byte position are multiplications by constants that are implementable by some XOR gates.

Similarly, the byte error correction values a and b are determined as

$$a = {α}^{i} [ \frac{{s}_{1} {S}_{1}^{2} + {s}_{3}}{{S}_{1}^{3} + {S}_{3}} ] + {s}_{1} + \frac{{s}_{2} {S}_{1}^{2} + {s}_{3} {S}_{1}}{{S}_{1}^{3} + {S}_{3}} + {α}^{2 i} [ \frac{{s}_{1} {S}_{1} + {s}_{2}}{{S}_{1}^{3} + {S}_{3}} ] , \qquad ( 40 )$$

$$b = {α}^{j} [ \frac{{s}_{1} {S}_{1}^{2} + {s}_{3}}{{S}_{1}^{3} + {S}_{3}} ] + {s}_{1} + \frac{{s}_{2} {S}_{1}^{2} + {s}_{3} {S}_{1}}{{S}_{1}^{3} + {S}_{3}} + {α}^{2 j} [ \frac{{s}_{1} {S}_{1} + {s}_{2}}{{S}_{1}^{3} + {S}_{3}} ] , \qquad ( 41 )$$

In general, a value v(L)

$$\begin{matrix}v ( L ) = {α}^{L} [ \frac{{s}_{1} {S}_{1}^{2} + {s}_{3}}{{S}_{1}^{3} + {S}_{3}} ] + {s}_{1} + \frac{{s}_{2} {S}_{1}^{2} + {s}_{3} {S}_{1}}{{S}_{1}^{3} + {S}_{3}} + {α}^{2 L} [ \frac{{s}_{1} {S}_{1} + {s}_{2}}{{S}_{1}^{3} + {S}_{3}} ] = \\ = {α}^{L} \cdot A + B + {α}^{2 L} \cdot C\end{matrix} \qquad ( 42 )$$

can be determined for any byte position L, irrespective of whether or not the byte position L is a byte error position. The value v(L) determined for the byte position L, which is not a byte error position, can be multiplied by the byte error position signal BPs_{L}=0. Irrespective of the determined value v(L), a correction with the value 0 is then performed in this byte position L. This corresponds to no correction.

The byte error position signal, with

$${BP}_{{S}_{i}} = {BP}_{{S}_{J}} = {BP}_{{S}_{k}} = 1 and {BP}_{{S}_{L}} = 0 for L \neq i , j , k$$

indicates that byte error values v(i), v(j), v(k) are used for correction and that the corrected byte error value v(L)^{cor}=BPs_{L}·v(L) is the same for all other byte positions equal to 0. The value of v(L) for L≠i,j,k is not relevant.

### Error Consideration

The following relationships are fulfilled for the errors under consideration:
1. For a 1-byte error it holds true that

$${s}_{1} = a \neq 0 \qquad ( 43 )$$

$$and$$

$${s}_{1} \cdot {s}_{3} + {s}_{2}^{2} = 0. \qquad ( 44 )$$

2. For a 2-byte error it holds true that

$${s}_{1} \cdot {s}_{3} + {s}_{2}^{2} = a \cdot b \cdot [ {α}^{2 i} + {α}^{2 j} ] \neq 0. \qquad ( 45 )$$

$$and$$

$$Det ( \begin{matrix}{s}_{1} & {s}_{2} & {s}_{3} \\ {s}_{2} & {s}_{3} & {s}_{4} \\ {s}_{3} & {s}_{4} & {s}_{5}\end{matrix} ) = {s}_{1} {s}_{3} {s}_{5} + {s}_{3}^{3} + {s}_{4}^{2} {s}_{1} + {s}_{2}^{2} {s}_{5} = 0. \qquad ( 46 )$$

3. For a 3-byte error,

$$Det ( \begin{matrix}{s}_{1} & {s}_{2} & {s}_{3} \\ {s}_{2} & {s}_{3} & {s}_{4} \\ {s}_{3} & {s}_{4} & {s}_{5}\end{matrix} ) = {s}_{1} {s}_{3} {s}_{5} + {s}_{3}^{3} + {s}_{4}^{2} {s}_{1} + {s}_{2}^{2} {s}_{5} == a \cdot b \cdot c \cdot \{ {α}^{2 i} + {α}^{2 j} \} \cdot \{ {α}^{2 i} + {α}^{2 k} \} \cdot \{ {α}^{2 j} + {α}^{2 k} \} \neq 0. \qquad ( 47 )$$

In the event of the 2-byte error in the i-th and j-th bytes, the byte error positions aⁱ and a^{j} can be determined as the solution, roots or zeros of the equation

$${x}^{2} \{ {s}_{1} {s}_{3} + {s}_{2}^{2} \} + x \{ {s}_{1} {s}_{4} + {s}_{2} {s}_{3} \} + {s}_{2} {s}_{4} + {s}_{3}^{2} = 0. \qquad ( 48 )$$

$$L ( x ) = {x}^{2} \{ {s}_{1} {s}_{3} + {s}_{2}^{2} \} + \{ {s}_{1} {s}_{4} + {s}_{2} {s}_{3} \} + {s}_{2} {s}_{4} + {s}_{3}^{2} .$$

can also be referred to as a second-degree locator polynomial.

Accordingly, the byte error positions for the 1-byte error are determined by a zero of a first-degree locator polynomial and, in general, the erroneous byte positions of a r-byte error for a t-byte-error-correcting code for

$$1 \leq τ \leq t$$

are determined by zeros of a T-th-degree locator polynomial.

If a codeword consists of N·m bits and thus N bytes, there are only N different byte positions that are possible as byte error positions. In a corresponding bit-correcting code, on the other hand, there are m·N possible erroneous bit positions.

A first-degree locator polynomial is used for a 1-byte error and a second-degree locator polynomial is used for a 2-byte error.

### Reed-Solomon Code, Additional Remarks

It is possible, in the event of a 2-byte error, to determine a byte error correction value a(i) for an i-th byte on the basis of just the syndrome components s₁, s₂, s₃ and the byte position i.

In this case, it is advantageous that multiple byte error correction values can be determined in parallel for, by way of example, at least three correctable bytes.

By way of example, it will be assumed that there is a 2-byte error. The byte error correction value for each byte position can be determined in parallel on the basis of the provided syndrome components s₁, s₂, Ss and the known position of each of the correctable bytes. A byte error correction value is determined for the two erroneous bytes and for at least one non-erroneous byte.

A byte error correction value determined for an i-th byte position matches the byte error value at this i-th position.

A byte error position signal that is also determined (optionally in parallel) stipulates whether there is a byte error in the byte under consideration, and the correction is performed using the byte error correction value. If the byte error position signal indicates that there is no byte error in the applicable position, no correction is performed using the byte error correction value determined for this position.

In other words: the byte error position signal determines the byte positions at which a correction is performed using the provided byte error correction value: if the byte error position signal indicates a byte error for a byte position, the correction is performed using the byte error correction value; if the byte error position signal indicates no byte error for this byte position, no correction is performed.

If a t-byte-error-correcting code is considered, the applicable byte error correction value can be determined for more than t correctable byte positions, even before the byte error position signals have been determined for (all or some of the) byte positions. The byte error correction value can also be determined in parallel with the byte error position signal.

If there is no byte error in an i-th byte, the byte error correction value determined for this i-th byte is not used for correction due to the value of the byte error position signal. In this case, it is not necessary for the byte error correction value determined for this non-erroneous byte to be equal to

$$0 = {\underbrace{0 , … , 0}}_{m}$$

as the byte error position signal means that correction is ruled out. Optionally, the byte error correction value for the i-th byte

$$0 = {\underbrace{0 , … , 0}}_{m}$$

can be set in this case.

If there is a 2-byte error, the byte error correction value a(i) of the i-th byte may be determined for a byte error position i such that it holds true that:

$$a ( i ) = \frac{{s}_{1} {s}_{3} + {s}_{2}^{2}}{{s}_{3} + {α}^{2 i} {s}_{1}} \qquad ( 49 )$$

If a byte position i in which a byte error has occurred is known for a 2-byte error, the byte error correction value a(i) is determined for the erroneous byte position i on the basis of equation (49) by the syndrome components s₁, s₂, s₃ and the value aⁱ determined from the byte position i.

For a byte position k, the byte error correction value a(k) is determined, for example in parallel, using

$$a ( k ) = \frac{{s}_{1} {s}_{3} + {s}_{2}^{2}}{{s}_{3} + {α}^{2 k} {s}_{1}} \qquad ( 50 )$$

irrespective of whether the byte position k is actually erroneous.

If the byte error position signal indicates that there is a byte error in the byte position k, an error correction for the k-th byte is performed using the byte error correction value a(k) determined for this byte position k.

If the byte error position signal indicates that there is no byte error in the byte position k, no error correction for the k-th byte is performed and the byte error correction value a(k) determined for this k-th byte is not used for error correction. Optionally, the byte error correction value can be set to 0.

The byte error correction value for a byte position may thus already be available even before it has been determined whether an error has actually occurred at this byte position.

The applicable byte error correction values for different byte positions can be determined in parallel. In particular, the byte error correction values for all correctable byte positions or for a subset of the correctable byte positions can be determined in parallel.

If the byte-error-correcting code is able to correct up to terroneous bytes, more than t byte error correction values can be determined in parallel, for example for all correctable byte positions or for a subset of at least t+1 correctable byte positions, irrespective of whether there is a byte error at a byte position.

The value of the byte error position signal determines whether the byte error correction value is used to correct the applicable byte.

Correctable byte positions may be for example all of the data bytes, a subset of the data bytes, check bytes, all bytes of a codeword of a t-byte-error-correcting code or a subset of the bytes of a codeword of the t-byte-error-correcting code.

The byte error position signal may be determined for example in such a way that it assumes a first value for a byte position if the byte of the byte position is erroneous and that it assumes a second value, which is different than the first value, if the byte of the byte position is not erroneous.

The byte error position signal can be determined using the applicable locator polynomial.

### Byte Error Position Signal for the 1-Byte Error

For a 1-byte error, the first-degree locator polynomial is

$$x \cdot {s}_{1} = {s}_{2} \qquad ( 51 )$$

with the solution or zero

$${α}^{i} = \frac{{s}_{2}}{{s}_{1}} . \qquad ( 52 )$$

The byte error correction value a(i) for the erroneous byte position i is

$$a ( i ) = {s}_{1} . \qquad ( 53 )$$

A byte error correction value

$$a ( k ) = {s}_{1} = a \qquad ( 54 )$$

is determined for each k-th byte.

If there is an error in the i-th byte with the byte error correction value a, and so s₁=a, a byte error correction value a(k)=a in accordance with equation (54) is determined for each byte k and used for the i-th byte that is actually to be corrected, and masked (e.g. set to zero) for the bytes that are not to be corrected. The decision as to whether or not a byte is corrected is taken on the basis of the value of the applicable byte error position signal.

In the event of a 1-byte error, a byte error position signal is determined for each byte using equation (51). The byte error position signal for the byte position i is
equal to 1 if a^{L} is a zero of the locator polynomial in accordance with equation (51) and equal to 0 if aⁱ is not a zero of the locator polynomial in accordance with equation (51).

The i-th byte is corrected only if aⁱ is a zero of the locator polynomial in accordance with equation (51).

### Byte Error Position Signal for the 2-Byte Error

The effect of the byte error position signal during correction of a 2-byte error is illustrated on the basis of an example:

If a t-byte-error-correcting code with t≥2 is used, then in the event of a 2-byte error the erroneous byte positions are determined by the two zeros of the second-degree locator polynomial in accordance with equation (48).

If the erroneous byte positions are the positions i and j, the byte error position signal is for example equal to 1 if aⁱ and a¹ are each a zero of the second-degree locator polynomial in accordance with equation (48) and equal to 0 in all other cases.

For each byte position k, a byte error correction value

$$a ( k ) = \frac{{s}_{1} \cdot {s}_{3} + {s}_{2}^{2}}{{s}_{3} + {α}^{2 k} {s}_{1}}$$

can be determined. At least some of these byte error correction values can be determined in parallel.

The value of the byte error position signal for the byte position k determines whether a correction is performed at this byte position k. If the byte error position signal is equal to 1, a correction is performed; if the byte error position signal is equal to 0, no correction is performed.

For the byte position k=i, the byte error correction value a(i) is determined in such a way that the erroneous i-th byte is corrected by using the byte error correction value a(i). Similarly, the byte error correction value a(j) for the byte position k=j is determined in such a way that the erroneous j-th byte is corrected by using the byte error correction value a(j).

For all other byte positions k with k≠i, j, there is no byte error, and so these byte positions require no correction. Even if a byte error correction value a(k) not equal to 0 has been determined, it is not used for correction because the byte error position signal assumes the value 0 at this byte position and therefore indicates that this byte position requires no correction.

### Handling of 1-Byte Errors, 2-Byte Errors and 3-Byte Errors

The text below describes how byte errors can be detected and distinguished from one another. A 2-byte-error-correcting code is considered by way of illustration. Additionally, 3-byte error detection is also described.

It is first assumed that there is only a 1-byte error or a 2-byte error. In such an example, it holds true for a 2-byte error in accordance with equation (45) that

$${s}_{1} {s}_{3} + {s}_{2}^{2} \neq 0$$

and for a 1-byte error both equations (43) and (44) apply

$${s}_{1} \neq 0$$

$${s}_{1} {s}_{3} + {s}_{2}^{2} = 0 .$$

Additionally, it is also necessary to distinguish the case in which neither a 1-byte error nor a 2-byte error has occurred. From s₁=0 alone, it can be concluded that neither a 1-byte error nor a 2-byte error has occurred.
If the likelihood of a 3-byte error is extremely small, it can be concluded for this case that no error has occurred.
2. Consideration is now given to the case in which there is only a 1-byte error or only a 2-byte error or only a 3-byte error. For a 3-byte error, it holds true in accordance with equation (47) that

$${s}_{1} {s}_{3} {s}_{5} + {s}_{3}^{3} + {s}_{4}^{2} {s}_{1} + {s}_{2}^{2} {s}_{5} \neq 0 .$$

Accordingly, it holds true for a 2-byte error or for a 1-byte error that:

$${s}_{1} {s}_{3} {s}_{5} + {s}_{3}^{3} + {s}_{4}^{2} {s}_{1} + {s}_{2}^{2} {s}_{5} = 0. \qquad ( 55 )$$

If there is a 2-byte error, equation (45) additionally applies

$${s}_{1} {s}_{3} + {s}_{2}^{2} \neq 0 .$$

For a 1-byte error, equations (43) and (44) again apply

$${s}_{1} \neq 0$$

$${s}_{1} {s}_{3} + {s}_{2}^{2} = 0 .$$

From the condition in accordance with equation (45) alone, it cannot be concluded that there is a 2-byte error because this condition also applies for the 3-byte error.

2-Byte errors can be corrected as follows: for each byte position i with i € {0,1, . . . , N−1}, a value L(aⁱ) of the second-degree locator polynomial is determined in accordance with

$$L ( {α}^{i} ) = {α}^{2 i} \{ {s}_{1} {s}_{3} + {s}_{2}^{2} \} + {α}^{i} \{ {s}_{1} {s}_{4} + {s}_{2} {s}_{3} \} + {s}_{2} {s}_{4} + {s}_{3}^{2} . \qquad ( 56 )$$

If L(aⁱ)=0, the i-th byte is corrected. If L(aⁱ)≠0, then the i-th byte is not corrected. A byte error position signal BPsᵢ can indicate whether or not the respective byte is corrected. The byte error position signal BPsᵢ is for example determined by

$${BP}_{{s}_{i}} = \{ \begin{matrix}1 & if & L ( {α}^{i} ) = 0 , \\ 0 & if & L ( {α}^{i} ) \neq 0\end{matrix} . \qquad ( 57 )$$

Circuit arrangements that perform operations in a Galois field GF(2^{m}) employ multipliers, constant multipliers, squarers, (third) power forming units or the like, for example. The circuitry implementation of individual operations of this type is known. An illustration is given below by way of example of how multipliers, squarers, third power forming units and constant multipliers can be realized in a Galois field determined for example by its modular polynomial. By way of example, m=5 is assumed, such that a byte consists of m=5 bits and the corresponding Galois field is GF(2⁵).

### Example in the Galois Field GF(2^{m}) where m=5

m=5 is chosen by way of example, such that the underlying Galois field

$$GF ( {2}^{m} ) = GF ( {2}^{5} ) = GF ( 32 )$$

comprises a total of 32 elements.

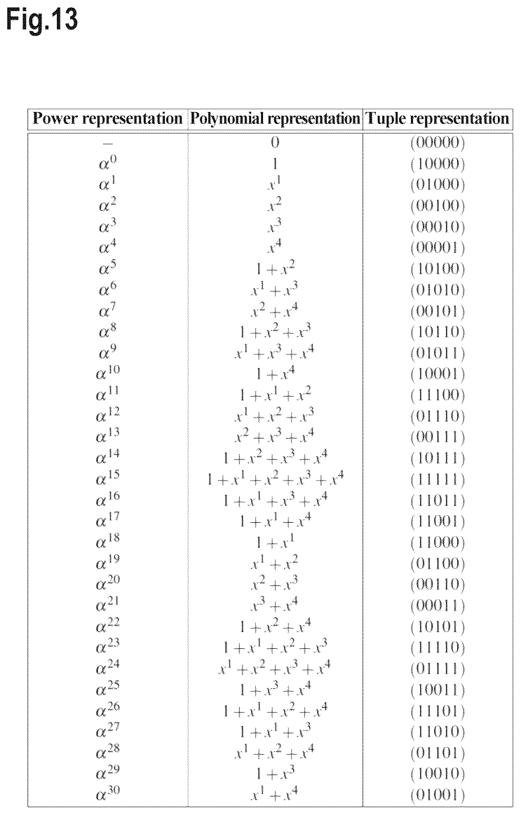

Elements of the Galois field GF(32) are presented in their various forms of representation in FIG. 13. The modular polynomial of the Galois field GF(32) is the polynomial

$$p ( x ) = 1 + {x}^{2} + {x}^{5} .$$

The first column of the table shown in FIG. 13 comprises the elements a≠0 of the GF(2⁵) for i=0,1, . . . ,30 in exponent representation (also referred to as exponential representation). The zero element of the field has no exponent representation. The second column of the table lists all elements in their polynomial representation for the associated modular polynomial p(x). The third column of the table shows the tuple or vector representation of the elements of the GF(2⁵). The vector representation of an element can be read directly from the polynomial representation. In this case, the five components of the vector representation correspond, from left to right, to the coefficients of the associated powers

x⁰,x¹,x²,x³,x⁴

in the polynomial representation.

The corresponding polynomial representation results from the power representation aⁱ by determining [xⁱ modulo (1+x²+x⁵)]. By way of example, the polynomial representation of a⁵ is equal to 1+x² since

$${x}^{5} modulo ( 1 + {x}^{2} + {x}^{5} ) = 1 + {x}^{2}$$

holds true.

The multiplication of two elements of the Galois field can be performed in the exponent representation or in the polynomial representation. If two elements of the Galois field GF(2^{m})=GF(2⁵) are given in the exponent representation aⁱ and aⁱ, their product results as:

$${α}^{i} \cdot {α}^{j} = {α}^{k} where k = ( i + j ) modulo ( {2}^{m} - 1 ) = ( i + j ) modulo 31.$$

If the elements to be multiplied in the Galois field are present in their vector representation or in their polynomial representation, their multiplication can be performed by a Galois field multiplier. The multiplication of two elements in their polynomial representation is described by way of example below. In order to multiply together two elements given as elements of the Galois field GF(2^{m})=GF(2⁵) in their polynomial representation, the polynomials should be multiplied together directly in the customary manner, and the result should be determined modulo the modular polynomial.

If the polynomials 1+x²+x³ and x+x³ are given, for example, then their direct multiplication yields

$$( 1 + {x}^{2} + {x}^{3} ) ( x + {x}^{3} ) = x + {x}^{4} + {x}^{5} + {x}^{6} .$$

### Owing to

$${x}^{5} = 1 + {x}^{2} modulo ( 1 + {x}^{2} + {x}^{5} ) and$$

$${x}^{6} = x + {x}^{3} modulo ( 1 + {x}^{2} + {x}^{5} )$$

it follows that

$$x + {x}^{4} + {x}^{5} + {x}^{6} = x + {x}^{4} + 1 + {x}^{2} + x + {x}^{3} = 1 + {x}^{2} + {x}^{3} + {x}^{4} .$$

The following thus holds true as a result:

$$( 1 + {x}^{2} + {x}^{3} ) \cdot ( x + {x}^{3} ) = 1 + {x}^{2} + {x}^{3} + {x}^{4} .$$

A description is given below of the case according to which a first element a(x) where

$$a ( x ) = {a}_{4} {x}^{4} + {a}_{3} {x}^{3} + {a}_{2} {x}^{2} + \text{?} x + {a}_{0}$$

$$\text{?} \text{indicates text missing or illegible when filed}$$

and a second element b (x) where

$$b ( x ) = {b}_{4} {x}^{4} + {b}_{3} {x}^{3} + {b}_{2} {x}^{2} + \text{?} x + {b}_{0}$$

$$\text{?} \text{indicates text missing or illegible when filed}$$

in the Galois field GF(2⁵) are multiplied by the modular polynomial

$$m ( x ) = {x}^{5} + {x}^{2} + 1.$$

Directly multiplying out the polynomials a(x) and b (x) yields firstly an 8-th degree polynomial. With

$${x}^{5} modulo ( 1 + {x}^{2} + {x}^{5} ) = 1 + {x}^{2} ,$$

$${x}^{6} modulo ( 1 + {x}^{2} + {x}^{5} ) = x + {x}^{3} ,$$

$${x}^{7} modulo ( 1 + {x}^{2} + {x}^{5} ) = {x}^{2} + {x}^{4} ,$$

$${x}^{8} modulo ( 1 + {x}^{2} + {x}^{5} ) = 1 + {x}^{2} + {x}^{3}$$

a fourth-degree polynomial arises as follows:

$${c}_{4} {x}^{4} + {c}_{3} {x}^{3} + {c}_{2} {x}^{2} + \text{?} + {c}_{0} = a ( x ) \cdot b ( x ) mod m ( x ) =$$

$$= ( {a}_{0} {b}_{4} + \text{?} {b}_{3} + {a}_{2} {b}_{2} + {a}_{3} \text{?} + {a}_{3} {b}_{4} + {a}_{4} {b}_{0} + {a}_{4} {b}_{3} ) \cdot {x}^{4} +$$

$$+ ( {a}_{0} {b}_{3} + \text{?} {b}_{2} + {a}_{2} \text{?} + {a}_{2} {b}_{4} + {a}_{3} {b}_{0} + {a}_{3} {b}_{3} + {a}_{4} {b}_{2} + {a}_{4} {b}_{3} ) \cdot {x}^{3} +$$

$$+ ( {a}_{0} {b}_{2} + \text{?} + \text{?} {b}_{4} + {a}_{2} {b}_{0} + {a}_{2} {b}_{3} + {a}_{3} {b}_{2} + {a}_{3} {b}_{4} + {a}_{4} \text{?} + {a}_{4} {b}_{3} + {a}_{4} {b}_{4} ) \cdot {x}^{2} +$$

$$+ ( {a}_{0} \text{?} + \text{?} {b}_{0} + {a}_{2} {b}_{4} + {a}_{3} {b}_{3} + {a}_{4} {b}_{2} ) \cdot \text{?} +$$

$$( {a}_{0} {b}_{0} + \text{?} {b}_{4} + {a}_{2} {b}_{3} + {a}_{3} {b}_{2} + {a}_{4} \text{?} + {a}_{4} {b}_{4} ) .$$

$$\text{?} \text{indicates text missing or illegible when filed}$$

This relationship is realized by a Galois field multiplier having five first binary inputs, five second binary inputs and five binary outputs. This is explained in greater detail below.

The binary values a₀, a₁, a₂, a₃, a₄ are present at the first five inputs of the Galois field multiplier and the binary values b₀, b₁, b₂, b₃, b₄ are present at the second five inputs, while the values c₀, c₁, c₂, c₃, c₄ where

$$( {a}_{0} {b}_{0} + {a}_{1} {b}_{4} + {a}_{2} {b}_{3} + {a}_{3} {b}_{2} + {a}_{4} {b}_{1} + {a}_{4} {b}_{4} ) = {c}_{0} , \qquad ( 58 )$$

$$( {a}_{0} {b}_{1} + {a}_{1} {b}_{0} + {a}_{2} {b}_{4} + {a}_{3} {b}_{3} + {a}_{4} {b}_{2} ) = {c}_{1} \qquad ( 59 )$$

$$( {a}_{0} {b}_{2} + {a}_{1} {b}_{1} + {a}_{1} {b}_{4} + {a}_{2} {b}_{0} + {a}_{2} {b}_{3} + {a}_{3} {b}_{2} + {a}_{3} {b}_{4} + {a}_{4} {b}_{1} + {a}_{4} {b}_{3} + {a}_{4} {b}_{4} ) = {c}_{2} \qquad ( 60 )$$

$$( {a}_{0} {b}_{3} + {a}_{1} {b}_{2} + {a}_{2} {b}_{1} + {a}_{2} {b}_{4} + {a}_{3} {b}_{0} + {a}_{3} {b}_{3} + {a}_{4} {b}_{2} + {a}_{4} {b}_{4} ) = {c}_{3} \qquad ( 61 )$$

$$( {a}_{0} {b}_{4} + {a}_{1} {b}_{3} + {a}_{2} {b}_{2} + {a}_{3} {b}_{1} + {a}_{3} {b}_{4} + {a}_{4} {b}_{0} + {a}_{4} {b}_{3} ) = {c}_{4} \qquad ( 62 )$$

are output at the five binary outputs. In this case, the symbol “+” denotes addition modulo 2 (XOR operation).

The implementation of equations (58) to (62) can be carried out by using a Galois field multiplier, for example using AND gates and XOR gates (exclusive-OR gates). By way of example, a synthesis tool can also be used in the context of the implementation.

If an element of the Galois field is squared, it is to be multiplied by itself. If, in the polynomial representation, an element is given as a polynomial

$$a ( x ) = {a}_{0} + {a}_{1} {x}^{1} + {a}_{2} {x}^{2} + {a}_{3} {x}^{3} + {a}_{4} {x}^{4}$$

it holds true that

$${( a ( x ) )}^{2} mod m ( x ) == [ {a}_{0} + {a}_{1} {x}^{2} + {a}_{2} {x}^{4} + {a}_{3} {x}^{6} + {a}_{4} {x}^{8} ] mod ( 1 + {x}^{2} + {x}^{5} ) == ( {a}_{2} ) {x}^{4} + ( {a}_{3} + {a}_{4} ) {x}^{3} + ( {a}_{1} + {a}_{4} ) {x}^{2} + {a}_{3} {x}^{1} + ( {a}_{0} + {a}_{4} ) .$$

Squaring an element in the Galois field GF(2⁵) can correspondingly be realized by a squarer having five binary inputs and five binary outputs. The binary values a₀, a₁, a₂, a₃, a₄ are fed in at its five binary inputs and the binary values d₀, d₁, d₂, d₃, d₄ are provided at the five binary outputs. It holds true that

$${a}_{0} + {a}_{4} = {d}_{0} , \qquad ( 63 )$$

$${a}_{3} = {d}_{1} , \qquad ( 64 )$$

$${a}_{1} + {a}_{4} = {d}_{2} , \qquad ( 65 )$$

$${a}_{3} + {a}_{4} = {d}_{3} , \qquad ( 66 )$$

$${a}_{2} = {d}_{4} , \qquad ( 67 )$$

wherein the symbol “+” once again denotes addition modulo 2 (XOR function).

In order to realize a squarer in the Galois field GF(2⁵) with the modular polynomial m(x)=1+x²+x⁵, equations (63) to (67) can be implemented by using XOR gates, for example.

On the basis of the example of the Galois field GF(2⁵) a description is given of how the third power of an element which is specified in its polynomial representation can be determined.

If the third power (a(x)) 3 of a polynomial

$$a ( x ) = {a}_{0} + {a}_{1} {x}^{1} + {a}_{2} {x}^{2} + {a}_{3} {x}^{3} + {a}_{4} {x}^{4}$$

is determined modulo the modular polynomial m(x)=1+x²+x⁶, it holds true that:

$${( a ( x ) )}^{3} mod m ( x ) == ( {a}_{0} {a}_{2} + {a}_{0} {a}_{4} + {a}_{1} {a}_{2} + {a}_{1} {a}_{3} + {a}_{1} {a}_{4} + {a}_{2} {a}_{3} + {a}_{2} {a}_{4} + {a}_{3} + {a}_{3} {a}_{4} ) \cdot {x}^{4} ++ ( {a}_{0} {a}_{4} + {a}_{1} + {a}_{2} + {a}_{2} {a}_{3} + {a}_{2} {a}_{4} + {a}_{3} + {a}_{4} ) \cdot {x}^{3} ++ ( {a}_{0} {a}_{1} + {a}_{0} {a}_{2} + {a}_{0} {a}_{4} + {a}_{1} {a}_{2} + {a}_{2} {a}_{4} + {a}_{3} {a}_{4} + {a}_{4} ) \cdot {x}^{2} ++ ( {a}_{0} {a}_{1} + {a}_{0} {a}_{3} + {a}_{2} + {a}_{3} + {a}_{3} {a}_{4} + {a}_{4} ) \cdot {x}^{1} ++ ( {a}_{0} + {a}_{0} {a}_{4} + {a}_{1} {a}_{2} + {a}_{1} {a}_{3} + {a}_{2} {a}_{3} )$$

Forming the third power of an element in the Galois field GF(2⁵) can correspondingly be realized by a third power forming unit having five binary inputs and five binary outputs. The binary values a₀, a₁, a₂, a₃, a₄ are fed to the five binary inputs and the binary values f₀, f₁, f₂, f₃, fa are provided at the five binary outputs. It holds true that:

$${f}_{0} = {a}_{0} + {a}_{0} {a}_{4} + {a}_{1} {a}_{2} + {a}_{1} {a}_{3} + {a}_{2} {a}_{3} \qquad ( 68 )$$

$${f}_{1} = {a}_{0} {a}_{1} + {a}_{0} {a}_{3} + {a}_{2} + {a}_{3} + {a}_{3} {a}_{4} + {a}_{4} \qquad ( 69 )$$

$${f}_{2} = {a}_{0} {a}_{1} + {a}_{0} {a}_{2} + {a}_{0} {a}_{4} + {a}_{1} {a}_{2} + {a}_{2} {a}_{4} + {a}_{3} {a}_{4} + {a}_{4} \qquad ( 70 )$$

$${f}_{3} = {a}_{0} {a}_{4} + {a}_{1} + {a}_{2} + {a}_{2} {a}_{3} + {a}_{2} {a}_{4} + {a}_{3} + {a}_{4} \qquad ( 71 )$$

$${f}_{4} = {a}_{0} {a}_{2} + {a}_{0} {a}_{4} + {a}_{1} {a}_{2} + {a}_{1} {a}_{3} + {a}_{1} {a}_{4} + {a}_{2} {a}_{3} + {a}_{2} {a}_{4} + {a}_{3} + {a}_{3} {a}_{4} \qquad ( 72 )$$

By way of example, a third power forming unit can be realized, in the present example in the Galois field GF(2⁵) with the modular polynomial m(x)=1+x²+x⁵, by merely implementing equations (68) to (72).

Alternatively, a third power forming unit can be realized from a squarer and a Galois field multiplier connected downstream. Moreover, higher powers of the element a(x) can be realized in a corresponding manner using suitable components.

An implementation of a constant multiplier in the Galois field GF(2^{m}) is illustrated below by way of example for m=5. The modular polynomial is

$$m ( x ) = 1 + {x}^{2} + {x}^{5} .$$

Let a∈GF(2⁵) be an arbitrary element of the Galois field with the following polynomial representation

$$a ( x ) = {a}_{0} + {a}_{1} x + {a}_{2} {x}^{2} + {a}_{3} {x}^{3} + {a}_{4} {x}^{4} . \qquad ( 73 )$$

As a constant to be multiplied, a₉ is chosen by way of example, the polynomial representation of which is given in accordance with the table shown in FIG. 13 by

$${α}^{9} ( x ) = x + {x}^{3} + {x}^{4} \qquad ( 74 )$$

As multiplication the following arises

$$a ( x ) \cdot {α}^{9} ( x ) modulo ( 1 + {x}^{2} + {x}^{5} ) = {b}_{0} + {b}_{1} x + {b}_{2} {x}^{2} + {b}_{3} {x}^{3} + {b}_{4} {x}^{4} \qquad ( 75 )$$

$$where$$

$${b}_{0} = {a}_{1} + {a}_{2} , \qquad ( 76 )$$

$${b}_{1} = {a}_{0} + {a}_{2} + {a}_{3} , \qquad ( 77 )$$

$${b}_{2} = {a}_{2} + {a}_{3} + {a}_{4} , \qquad ( 78 )$$

$${b}_{3} = {a}_{0} + {a}_{3} + {a}_{4} , \qquad ( 79 )$$

$${b}_{4} = {a}_{0} + {a}_{1} + {a}_{4} . \qquad ( 80 )$$

The output values b₀, . . . ,b₄ are derived from the input values a₀, . . . ,a₄ in accordance with the relationships represented in equations (76) to (80), such that the output values are determined from the input values by XOR functions. In this case, the symbol “+” denotes addition modulo 2 (XOR operation). Accordingly, the constant multiplier can be realized by using XOR gates.

### Description of a Byte Error Position Signal Forming Unit for Forming Byte Error Position Signals

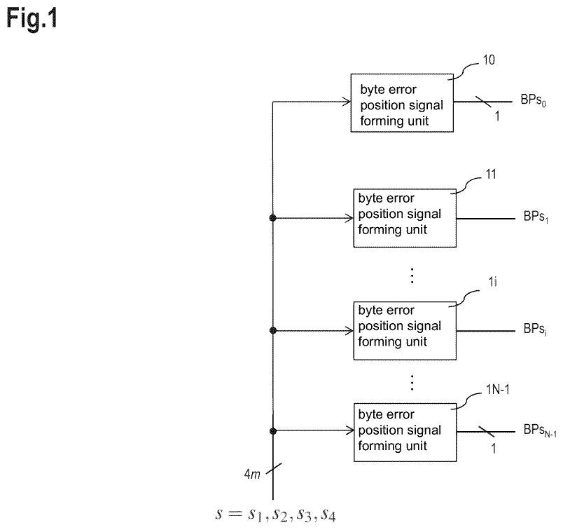

FIG. 1 shows an exemplary circuit arrangement for determining byte error position signals. A 2-byte-error-correcting error code having code words composed of n bytes is considered by way of example, wherein each byte has in each case m bits.

The circuit arrangement has N byte error position signal forming units 10, 11, . . . , 1i, . . . , 1N−1, which provide binary byte error position signals BPs₀, BPs₁, . . . , BPsᵢ, . . . , BPs_{N-1} via their respective 1-bit-wide output.

At respective 4·m-bit-wide inputs of the N byte error position signal forming units 10, 11, . . . , 1i, . . . , 1N−1, a 4·m-bit-wide error syndrome

$$s = {s}_{1} , {s}_{2} , {s}_{3} , {s}_{4}$$

provided by a syndrome generator (not illustrated in FIG. 1) is present, which consists of the respective m-bit-wide syndrome components s₁, s₂, s₃, s₄.

If all bytes are corrected in the case of an error, then N=n holds true. If fewer than n bytes are corrected in the case of an error, N<n holds true. By way of example, it is possible that only data bytes are corrected in the case of an error. Check bytes could not then be corrected in such an example.

The byte error position signal forming unit 10 is configured for example such
that it outputs the byte error position signal BPs₀=1 if the following holds true:

$${α}^{2 \cdot 0} \{ {s}_{1} {s}_{3} + {s}_{2}^{2} \} + {α}^{0} \{ {s}_{1} {s}_{4} + {s}_{2} {s}_{3} \} + {s}_{2} {s}_{4} + {s}_{3}^{2} = 0$$

that it outputs the byte error position signal BPs₀=0 if the following holds true:

$${α}^{2 \cdot 0} \{ {s}_{1} {s}_{3} + {s}_{2}^{2} \} + {α}^{0} \{ {s}_{1} {s}_{4} + {s}_{2} {s}_{3} \} + {s}_{2} {s}_{4} + {s}_{3}^{2} \neq 0$$

The byte error position signal forming unit 11 is configured for example such
that it outputs the byte error position signal BPs₁₌₁ if the following holds true:

$${α}^{2 \cdot 1} \{ {s}_{1} {s}_{3} + {s}_{2}^{2} \} + {α}^{1} \{ {s}_{1} {s}_{4} + {s}_{2} {s}_{3} \} + {s}_{2} {s}_{4} + {s}_{3}^{2} = 0$$

that it outputs the byte error position signal BPs₁₌₀ if the following holds true:

$${α}^{2 \cdot 1} \{ {s}_{1} {s}_{3} + {s}_{2}^{2} \} + {α}^{1} \{ {s}_{1} {s}_{4} + {s}_{2} {s}_{3} \} + {s}_{2} {s}_{4} + {s}_{3}^{2} \neq 0$$

The byte error position signal forming unit 1 i is configured for example such
that it outputs the byte error position signal BPsᵢ=1 if the following holds true:

$${α}^{2 \cdot i} \{ {s}_{1} {s}_{3} + {s}_{2}^{2} \} + {α}^{i} \{ {s}_{1} {s}_{4} + {s}_{2} {s}_{3} \} + {s}_{2} {s}_{4} + {s}_{3}^{2} = 0$$

that it outputs the byte error position signal BPsᵢ=0 if the following holds true:

$${α}^{2 \cdot i} \{ {s}_{1} {s}_{3} + {s}_{2}^{2} \} + {α}^{i} \{ {s}_{1} {s}_{4} + {s}_{2} {s}_{3} \} + {s}_{2} {s}_{4} + {s}_{3}^{2} \neq 0$$

The byte error position signal forming unit 1N−1 is configured for example such
that it outputs the byte error position signal BPs_{N-1}=1 if the following holds true:

$${α}^{2 \cdot ( N - 1 )} \{ {s}_{1} {s}_{3} + {s}_{2}^{2} \} + {α}^{N - 1} \{ {s}_{1} {s}_{4} + {s}_{2} {s}_{3} \} + {s}_{2} {s}_{4} + {s}_{3}^{2} = 0$$

that it outputs the byte error position signal BPs_{N-1}=0 if the following holds true:

$${α}^{2 \cdot ( N - 1 )} \{ {s}_{1} {s}_{3} + {s}_{2}^{2} \} + {α}^{N - 1} \{ {s}_{1} {s}_{4} + {s}_{2} {s}_{3} \} + {s}_{2} {s}_{4} + {s}_{3}^{2} \neq 0$$

In this case, the respective exponents of a are to be interpreted modulo 2^{m}-1.

If a 2-byte error is present and if the j-th byte and the k-th byte are erroneous, then for i=j and for i=k the byte error position signals BPsᵢ are equal to 1, while all other byte error position signals BPsᵢ where I≠j, k are equal to 0, wherein it holds true that:

$$0 \leq i , j , k , l \leq N - 1 ,$$

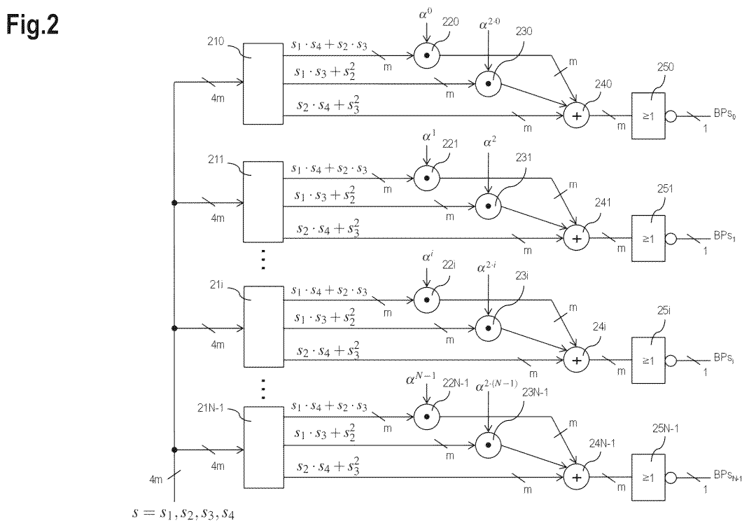

i·a⁰=1 and 1 is the unity of the Galois field GF(2^{m}).
Byte Error Position Signal Forming Unit in Accordance with FIG. 2

FIG. 2 shows a circuit arrangement which represents one possible configuration of the circuit arrangement shown in FIG. 1.

The byte error position signal forming unit 10 shown in FIG. 1 comprises
a subcircuit 210 having a 4·m-bit-wide input for inputting the components s₁, s₂, s₃ and s₄ of the error syndrome s=s₁, s₂, s₃, s₄ and three respective m-bit-wide outputs,
a constant multiplier 220 having a first m-bit-wide input, a second m-bit-wide input and an m-bit-wide output,
a constant multiplier 230 having a first m-bit-wide input, a second m-bit-wide input and an m-bit-wide output,
an XOR circuit 240 having three respective m-bit-wide inputs and an m-bit-wide output, and
a NOR circuit 250 (NOT-OR circuit) having an m-bit-wide input and a 1-bit-wide binary output.

The subcircuit 210 is configured in such a way that upon the error syndrome s being input, it
outputs s₁· s₄+s₂. Ss at the first output,
outputs s₁·s₃+s₂ at the second output and
outputs s₂·s₄+s₃ at the third output.

The first output of the subcircuit 210 is connected to the first input of the constant multiplier 220. The constant q°=1 is present at the second input of the constant multiplier 220, such that

$${α}^{0} ( {s}_{1} \cdot {s}_{4} + {s}_{2} \cdot {s}_{3} ) = {s}_{1} \cdot {s}_{4} + {s}_{2} \cdot {s}_{3}$$

is provided at the output of the constant multiplier 220.

The output of the constant multiplier 220 is connected to the first input of the XOR circuit 240.

The second output of the subcircuit 210 is connected to the first input of the constant multiplier 230. The constant a^{2·0}=a⁰ is present at the second input of the constant multiplier 230, such that

$${α}^{0} ( {s}_{1} \cdot {s}_{3} + {s}_{2}^{2} ) = {s}_{1} \cdot {s}_{3} + {s}_{2}^{2}$$

is provided at the output of the constant multiplier 230.

The output of the constant multiplier 230 is connected to the second input of the XOR circuit 240.

The third output of the subcircuit 210 is connected to the third input of the XOR circuit 240.

The XOR circuit 240 forms for example a component-by-component XOR function for the respective m-bit-wide values present at its three inputs and provides the value

$${v}^{0} = {α}^{0} ( {s}_{1} \cdot {s}_{4} + {s}_{2} \cdot {s}_{3} ) + {α}^{0} ( {s}_{1} \cdot {s}_{3} + {s}_{2}^{2} ) + {s}_{2} \cdot {s}_{4} + {s}_{3}^{2}$$

at its m-bit-wide output, this value being passed to the input of the NOR circuit 250. The NOR circuit 250 provides at its output
the binary value BPs₀=1 if v⁰=0 holds true and
the binary value BPs₀=0 if v⁰ ≠0 holds true.

The byte error position signal forming unit 11 shown in FIG. 1 comprises
a subcircuit 211 having a 4·m-bit-wide input for inputting the components s₁, s₂, s₃, s₄ of the error syndrome s=s₁, s₂, s₃, s₄ and three respective m-bit-wide outputs,
a constant multiplier 221 having a first m-bit-wide input, a second m-bit-wide input and an m-bit-wide output,
a constant multiplier 231 having a first m-bit-wide input, a second m-bit-wide input and an m-bit-wide output,
an XOR circuit 241 having three respective m-bit-wide inputs and an m-bit-wide output, and
a NOR circuit 251 having an m-bit-wide input and a 1-bit-wide binary output.

The subcircuit 211 is configured in such a way that, upon the error syndrome s being input, it outputs s₁. s₄+s₂. Ss at the first output, outputs s₁. s₃+s₂ at the second output and outputs s₂. s₄+s₃² at the third output.

The first output of the subcircuit 211 is connected to the first input of the constant multiplier 221. The constant a¹ is present at the second input of the constant multiplier 221, such that

$${α}^{1} ( {s}_{1} \cdot {s}_{4} + {s}_{2} \cdot {s}_{3} )$$

is provided at the output of the constant multiplier 221.

The output of the constant multiplier 221 is connected to the first input of the XOR circuit 241.

The second output of the subcircuit 211 is connected to the first input of the constant multiplier 231. The constant a² is present at the second input of the constant multiplier 231, such that

$${α}^{2} ( {s}_{1} \cdot {s}_{3} + {s}_{2}^{2} )$$

is provided at the output of the constant multiplier 231.

The output of the constant multiplier 231 is connected to the second input of the XOR circuit 241.

The third output of the subcircuit 211 is connected to the third input of the XOR circuit 241.

The XOR circuit 241 forms for example a component-by-component XOR function for the respective m-bit-wide values present at its three inputs and provides the value

$${v}^{1} = {α}^{1} ( {s}_{1} \cdot {s}_{4} + {s}_{2} \cdot {s}_{3} ) + {α}^{2} ( {s}_{1} \cdot {s}_{3} + {s}_{2}^{2} ) + {s}_{2} \cdot {s}_{4} + {s}_{3}^{2}$$

at its m-bit-wide output, this value being passed to the input of the NOR circuit 251. The NOR circuit 251 provides at its output
the binary value BPs₁₌₁ if v¹=0 holds true and
the binary value BPs₁₌₀ if v¹≠0 holds true.

The byte error position signal forming unit 1i shown in FIG. 1 comprises
a subcircuit 21i having a 4·m-bit-wide input for inputting the components s₁, s₂, s₃ and s₄ of the error syndrome s=s₁, s₂, s₃, s₄ and three respective m-bit-wide outputs,
a constant multiplier 22i having a first m-bit-wide input, a second m-bit-wide input and an m-bit-wide output,
a constant multiplier 23i having a first m-bit-wide input, a second m-bit-wide input and an m-bit-wide output,
an XOR circuit 24i having three respective m-bit-wide inputs and an m-bit-wide output, and
a NOR circuit 25i having an m-bit-wide input and a 1-bit-wide binary output.

The subcircuit 21i is configured in such a way that, upon the error syndrome s being input, it
outputs s₁· s₄+s₂. Ss at the first output,
outputs s₁. s₃+s₂ at the second output and
outputs s₂. s₄+s₃ at the third output.

The first output of the subcircuit 21i is connected to the first input of the constant multiplier 22i. The constant aⁱ is present at the second input of the constant multiplier 22i, such that

$${α}^{i} ( {s}_{1} \cdot {s}_{4} + {s}_{2} \cdot {s}_{3} )$$

is provided at the output of the constant multiplier 22i.

The output of the constant multiplier 22i is connected to the first input of the XOR circuit 24i.

The second output of the subcircuit 21i is connected to the first input of the constant multiplier 23i. The constant a²⁻ⁱ is present at the second input of the constant multiplier 23i, such that

$${α}^{2 \cdot i} ( {s}_{1} \cdot {s}_{3} + {s}_{2}^{2} )$$

is provided at the output of the constant multiplier 23i.

The output of the constant multiplier 23i is connected to the second input of the XOR circuit 24i.

The third output of the subcircuit 21i is connected to the third input of the XOR circuit 24i.

The XOR circuit 24i forms for example a component-by-component XOR function for the respective m-bit-wide values present at its three inputs and provides at its m-bit-wide output

$${v}^{i} = {α}^{i} ( {s}_{1} \cdot {s}_{4} + {s}_{2} \cdot {s}_{3} ) + {α}^{2 \cdot i} ( {s}_{1} \cdot {s}_{3} + {s}_{2}^{2} ) + {s}_{2} \cdot {s}_{4} + {s}_{3}^{2}$$

which is passed to the input of the NOR circuit 25i. The NOR circuit 25i provides at its output
the binary value BPsᵢ=1 if vⁱ=0 holds true and the binary value BPsᵢ=0 if vⁱ≠0 holds true.

The byte error position signal forming unit 1N−1 shown in FIG. 1 comprises
a subcircuit 21N−1 having a 4·m-bit-wide input for inputting the components s₁, s₂, s₃ and s₄ of the error syndrome s=s₁, s₂, s₃, s₄ and three respective m-bit-wide outputs,
a constant multiplier 22N−1 having a first m-bit-wide input, a second m-bit-wide input and an m-bit-wide output,
a constant multiplier 23N−1 having a first m-bit-wide input, a second m-bit-wide input and an m-bit-wide output,
an XOR circuit 24N−1 having three respective m-bit-wide inputs and an m-bit-wide output, and
a NOR circuit 25N−1 having an m-bit-wide input and a 1-bit-wide binary output.

The subcircuit 21N−1 is configured in such a way that, upon the error syndrome s being input, it
outputs s₁· s₄+s₂· s₃ at the first output,
outputs s₁· s₃+s₂ at the second output and
outputs s₂·s₄+s₃ at the third output.

The first output of the subcircuit 21N−1 is connected to the first input of the constant multiplier 22N−1. The constant a^{N-1} is present at the second input of the constant multiplier 22N−1, such that

$${α}^{N - 1} ( {s}_{1} \cdot {s}_{4} + {s}_{2} \cdot {s}_{3} )$$

is provided at the output of the constant multiplier 22N−1.

The output of the constant multiplier 22N−1 is connected to the first input of the XOR circuit 24N−1.

The second output of the subcircuit 21N−1 is connected to the first input of the constant multiplier 23N−1. The constant a² (N−1) is present at the second input of the constant multiplier 23N−1, such that

$${α}^{2 \cdot ( N - 1 )} ( {s}_{1} \cdot {s}_{3} + {s}_{2}^{2} )$$

is provided at the output of the constant multiplier 23N−1.

The output of the constant multiplier 23N−1 is connected to the second input of the XOR circuit 24N−1.

The third output of the subcircuit 21N−1 is connected to the third input of the XOR circuit 24N−1.

The XOR circuit 24N−1 forms for example a component-by-component XOR function for the respective m-bit-wide values present at its three inputs and provides the value

$${v}^{N - 1} = {α}^{N - 1} ( {s}_{1} \cdot {s}_{4} + {s}_{2} \cdot {s}_{3} ) + {α}^{2 \cdot ( N - 1 )} ( {s}_{1} \cdot {s}_{3} + {s}_{2}^{2} ) + {s}_{2} \cdot {s}_{4} + {s}_{3}^{2}$$

at its m-bit-wide output, this value being passed to the input of the NOR circuit 25N−1. The NOR circuit 25N−1 provides at its output
the binary value BPs_{N-1}=1 if v^{N-1}=0 holds true and
the binary value BPs_{N-1}=0 if v^{N-1}+0 holds true.

### Exemplary Combination of the Subcircuits

The subcircuits 210, 211, . . . , 21i, . . . , 21N−1 in FIG. 2 are functionally identical. It is thus possible for these subcircuits to be combined in one subcircuit 31.

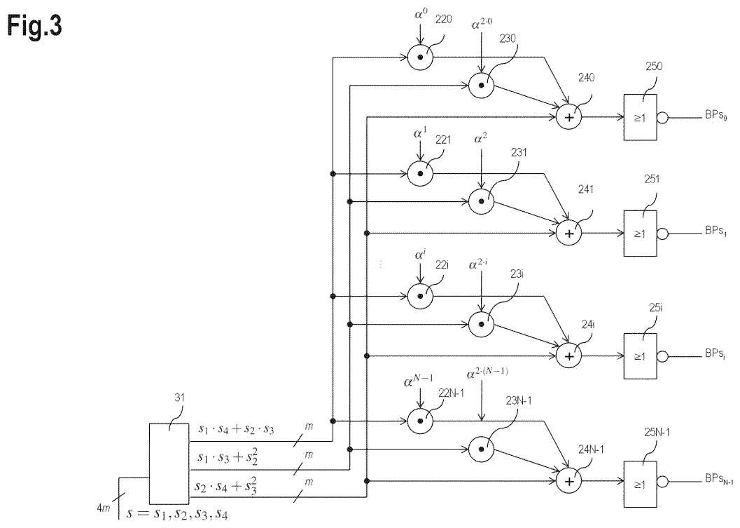

FIG. 3 shows such a subcircuit 31 that combines the subcircuits 210, 211, . . . , 21i, . . . , 21N−1. The remaining circuit part shown in FIG. 3 is identical to FIG. 2.

By way of example, the byte error position signal forming units 10, 11, . . . , 1i, . . . 1N−1 in accordance with FIG. 1 can utilize the common subcircuit 31.

### Exemplary Implementation of the Subcircuit 31

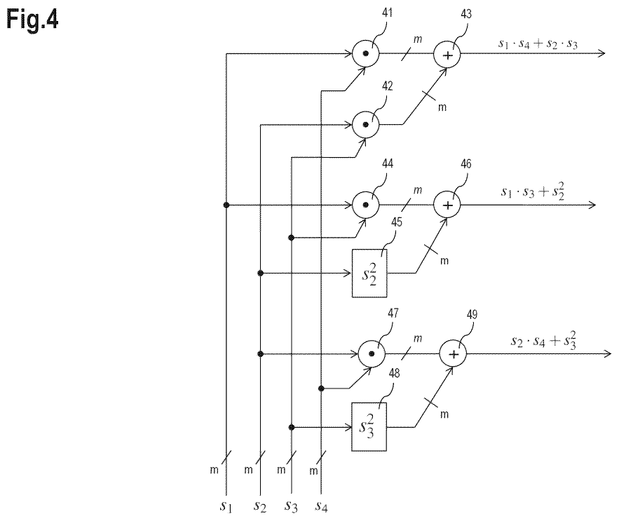

FIG. 4 shows one possible implementation of the subcircuit 31 illustrated in FIG. 3.

The subcircuit 31 has four respective m-bit-wide inputs for inputting the components s₁, s₂, s₃, s₄ which form the syndrome s. Furthermore, provision is made for four multipliers 41, 42, 44 and 47 each having two m-bit-wide inputs and an m-bit-wide output, two squarers 45 and 48 each having an m-bit-wide input and an m-bit-wide output, and three XOR circuits 43, 46 and 49 each having two m-bit-wide inputs and an m-bit-wide output.

The XOR circuits 43, 46, 49 each carry out a component-by-component XOR function for the m-component values present at their respective inputs. The multipliers carry out a multiplication in the Galois field GF(2^{m}), and the squarers square their operands present at the input likewise in the Galois field GF(2^{m}).

The input carrying the component s₁ is connected to the first input of the multiplier 41 and to the first input of the multiplier 44.

The input carrying the component s₂ is connected to the first input of the multiplier 42, to the first input of the multiplier 47 and to the input of the squarer 45.

The input carrying the component s₃ is connected to the second input of the multiplier 42, to the second input of the multiplier 44 and to the input of the squarer 48.

The input carrying the component s₄ is connected to the second input of the multiplier 41 and to the second input of the multiplier 47.

The output of the multiplier 41 is passed into the first input of the XOR circuit 43. The output of the multiplier 42 is passed into the second input of the XOR circuit 43. The signal s₁s₄+s₂Ss is provided at the output of the XOR circuit 43.

The output of the multiplier 44 is passed into the first input of the XOR circuit 46. The output of the squarer 45 is connected to the second input of the XOR circuit 46. The signal s₁s₃+s₂ ² is provided at the output of the XOR circuit 46.

The output of the multiplier 47 is passed into the first input of the XOR circuit 49. The output of the squarer 48 is connected to the second input of the XOR circuit 49. The signal s₂s₄+s₃² is provided at the output of the XOR circuit 49.

### Byte Error Correction Values for 2-Byte Errors

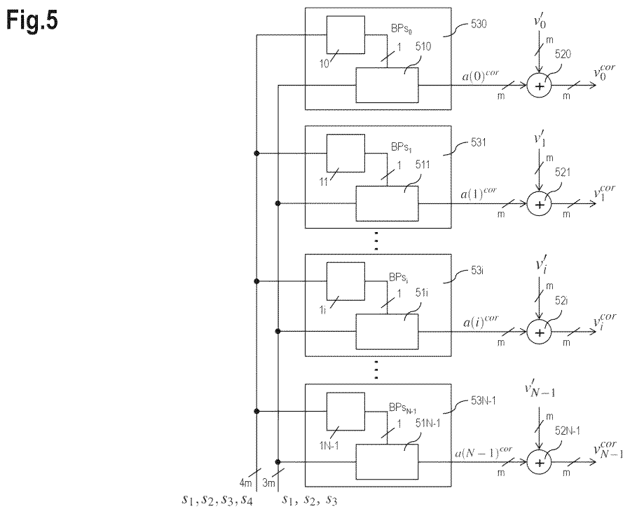

FIG. 5 shows an exemplary circuit for forming byte error correction values for a total of N bytes in the case of a 2-byte error. The N bytes considered are numbered from 0 to N−1.

A byte error correction value a(i)^{cor} for the i-th byte where 0≤i≤N−1 is determined depending on the current error syndrome s, the byte position i and the byte error position signal BPsᵢ in accordance with

$${a ( i )}^{cor} = {BPs}_{i} \cdot a ( i ) .$$

By way of example, byte error correction values are determined for all N byte positions. The byte error correction values are masked for byte positions which are not erroneous. By way of example, the masking can be carried out by multiplying a byte error position signal having the value 0 by the byte error correction value.

If a 2-byte error is present in the byte positions i and j, the i-th and j-th bytes can be corrected by the i-th and j-th bytes being XORed component by component with a corresponding byte error correction value a(i)^{cor}=a(i)+0 and respectively a(j)^{cor}=a(j)+0.

The bytes which are not erroneous are not corrected. For this purpose, for their byte positions the byte error correction values are set to 0 (e.g. by using the above-explained multiplication of the byte error correction value by 0) and the correct bytes are then XORed component by component with this value 0. As a result of the XORing with the value 0, the original value remains unchanged.

For the i-th erroneous byte the byte error position signal BPsᵢ=1 and the following holds true:

$${a ( i )}^{cor} = {BPs}_{i} \cdot a ( i ) = a ( i ) .$$

For the j-th erroneous byte the byte error position signal BPsⱼ=1 and the following holds true:

$${a ( j )}^{cor} = {BPs}_{j} \cdot a ( j ) = a ( j ) .$$

For a k-th, non-erroneous byte where k≠i, j, the byte error position signal BPsₖ=0 and the following holds true:

$${a ( k )}^{cor} = {BPs}_{k} \cdot a ( k ) = 0.$$

If the k-th byte where k+i, j is not erroneous, it is not corrected. In accordance with the example shown in FIG. 5, this can be achieved by the k-th byte being XORed component by component with the value 0, such that the value of the k-th byte does not change. The byte error position signal thus masks the byte error correction value as 0, such that no correction is carried out.

If, in the case of a 2-byte error, a first byte error is present in the byte position j and a second byte error is present in the byte position k, the byte error correction values a(j)^{cor} and a(k)^{cor} are not equal to 0, while the byte error correction values a(i)^{cor} for i≠j,k are in each case equal to 0. It then also holds true that

$${BPs}_{j} = {BPs}_{k} = 1$$

$$and$$

$${BPs}_{i} = 0 for i \neq j , k .$$

FIG. 5 comprises N byte error position signal forming units 10, 11, . . . , 1i, . . . , 1N−1 for forming the byte error position signals BPs₀, BPs₁, . . . , BPsᵢ, . . . , BPs_{N-1} each having a 4·m-bit-wide (or a 4·m-dimensional) input for inputting the error syndrome s and a 1-bit-wide (or 1-dimensional) output for outputting the byte error position signals BPs₀, BPs₁, . . . , BPsᵢ, . . . , BPs_{N-1}.

FIG. 5 furthermore shows N byte error correction value forming units 510, 511, . . . , 51i, . . . , 5N−1 each having
a first 1-bit-wide input for inputting a byte error position signal,
a second 3·m-bit-wide input for inputting the components s₁, s₂, s₃ of the error syndrome s and
an m-bit-wide output for outputting one of the byte error correction values a(0)^{cor}, a(1)^{cor}, . . . , a(i)^{cor}, . . . , a(N−1)^{cor} for the corresponding byte positions.

Furthermore, FIG. 5 comprises N XOR circuits 520, 521, . . . , 52i, . . . , 52N−1 each having
an m-bit-wide first input for inputting the corresponding byte error correction value,
a second m-bit-wide input for inputting the corresponding byte to be corrected, and an m-bit-wide output for outputting the respective m-bit-wide corrected bytes.

The current error syndrome s is present at the 4·m-bit-wide input of the byte error position signal forming unit 10. The byte error position signal BPs₀ is output at the 1-bit-wide output of the byte error position signal forming unit 10, which is connected to the first input of the byte error correction value forming unit 510.

The components s₁, s₂, s₃ of the error syndrome s are present at the second 3·m-bit-wide input of the byte error correction value forming unit 510. The byte error correction value forming unit 510 provides the byte error correction value a(0)^{cor} at its output. The output of the byte error correction value forming unit 510 is connected to the first input of the XOR circuit 520. The possibly erroneous byte value v; of the 0-th byte is present at the second input of the XOR circuit 520. The XOR circuit 520 forms the component-by-component XOR function for the possibly erroneous byte value v′ and the byte error correction value a(0)^{cor} and outputs the value

$${v}_{0}^{′} + {a ( 0 )}^{cor} = {v}_{0}^{cor}$$

at its output. The byte error correction value a(0)^{cor}
is equal to 0 if the 0-th byte is correct and BPs₀=0, and
is not equal to 0 if the 0-th byte is erroneous and BPs₀=1.

The current error syndrome s is present at the 4·m-bit-wide input of the byte error position signal forming unit 11. The byte error position signal BPsᵢ is output at the 1-bit-wide output of the byte error position signal forming unit 11, which is connected to the first input of the byte error correction value forming unit 511.

The components s₁, s₂, s₃ of the error syndrome s are present at the second 3·m-bit-wide input of the byte error correction value forming unit 511. The byte error correction value forming unit 511 provides the byte error correction value a(1)^{cor} at its output. The output of the byte error correction value forming unit 511 is connected to the first input of the XOR circuit 521. The possibly erroneous byte value v′₁ of the 1-st byte is present at the second input of the XOR circuit 521. The XOR circuit 521 forms the component-by-component XOR function for the possibly erroneous byte value v′ and the byte error correction value a(1)^{cor} and outputs the value

$${v}_{1}^{′} + {a ( 1 )}^{cor} = {v}_{1}^{cor}$$

at its output. The byte error correction value a(1)^{cor}
is equal to 0 if the 1-st byte is correct and BPs₁=0, and
is not equal to 0 if the 1-st byte is erroneous and BPs₁=1.

The current error syndrome s is present at the 4·m-bit-wide input of the byte error position signal forming unit 1i. The byte error position signal BPsᵢ is output at the 1-bit-wide output of the byte error position signal forming unit 1i, which is connected to the first input of the byte error correction value forming unit 51i.

The components s₁, s₂, Ss of the error syndrome s are present at the second 3·m-bit-wide input of the byte error correction value forming unit 51i. The byte error correction value forming unit 51i provides the byte error correction value a(i)^{cor} at its output. The output of the byte error correction value forming unit 51i is connected to the first input of the XOR circuit 52i. The possibly erroneous byte value v′ᵢ of the i-th byte is present at the second input of the XOR circuit 52i. The XOR circuit 52i forms the component-by-component XOR function for the possibly erroneous byte value v′ and the byte error correction value a(i)^{cor} and outputs the value

$${v}_{i}^{′} + {a ( i )}^{cor} = {v}_{i}^{cor}$$

at its output. The byte error correction value a(i)^{cor}
is equal to 0 if the i-th byte is correct and BPsᵢ=0, and
is not equal to 0 if the i-th byte is erroneous and BPsᵢ=1.

The current error syndrome s is present at the 4·m-bit-wide input of the byte error position signal forming unit 1N−1. The byte error position signal BPs_{N-1} is output at the 1-bit-wide output of the byte error position signal forming unit 1N−1, which is connected to the first input of the byte error correction value forming unit 51N−1.

The components s₁, s₂, s₃ of the error syndrome s are present at the second 3·m-bit-wide input of the byte error correction value forming unit 51N−1. The byte error correction value forming unit 51N−1 provides the byte error correction value a(N−1)^{cor} at its output. The output of the byte error correction value forming unit 51N−1 is connected to the first input of the XOR circuit 52N−1. The possibly erroneous byte value v′_{N-1} of the (N−1)-th byte is present at the second input of the XOR circuit 52N−1. The XOR circuit 52N−1 forms the component-by-component XOR function for the possibly erroneous byte value v′_{N-1} and the byte error correction value a(N−1)^{cor} and outputs the value

$${v}_{N - 1}^{′} + {a ( N - 1 )}^{cor} = {v}_{N - 1}^{cor}$$

at its output. The byte error correction value a(N−1)^{cor}
is equal to 0 if the (N−1)-th byte is correct and BPs_{N-1}=0, and
is not equal to 0 if the (N−1)-th byte is erroneous and BPs_{N-1}=1.

In this regard, a byte corrector 530 can comprise the byte error position signal forming unit 10 and the byte error correction value forming unit 510, a byte corrector 531 can comprise the byte error position signal forming unit 11 and the byte error correction value forming unit 511, a byte corrector 53i can comprise the byte error position signal forming unit 1i and the byte error correction value forming unit 51i and a byte corrector 53N−1 can comprise the byte error position signal forming unit 1N−1 and the byte error correction value forming unit 51N−1. Correspondingly, the byte correctors 530, 531, . . . , 53i, . . . , 53N−1 can be referred to as byte correctors for 2-byte errors.

In this example, the byte correctors for a 2-byte error output the byte error correction values for those two byte positions which are erroneous. For byte positions having no error, the byte error correction value is equal to 0.

For an erroneous byte position i it holds true that:

$${a ( i )}^{cor} = a ( i ) .$$

For a byte position j that is not erroneous it holds true that:

$${a ( j )}^{cor} = 0.$$

In this case, a(i) is the byte error correction value of the i-th byte.

In order to clearly illustrate that the byte error position signal forming units form the corresponding byte error position signal depending on the four components s₁, s₂, s₃, s₄ of the error syndrome s and that the byte error correction value forming units form the corresponding byte error correction value depending on the three components s₁, s₂, s₃ of the error syndrome s, FIG. 5 illustrates by way of example two input lines, an input line for inputting the components s₁, s₂, s₃, s₄ and a further input line for inputting the components s₁, s₂, s₃. These lines can also be combined for the components s₁, s₂, s₃.

For r=0, . . . , N−1, a byte error correction value forming unit 51r is configured such that it forms at its m-bit-wide output, which is connected to the first m-bit-wide input of an XOR circuit 52r, in the case of a 2-byte error, the byte error correction value such that the following holds true:

$${a ( r )}^{cor} = \frac{{s}_{1} {s}_{3} + {s}_{2}^{2}}{{s}_{3} + {α}^{2 r} {s}_{1}} \cdot {BPs}_{r} .$$

If, in the case of a 2-byte error, the j-th and k-th bytes are erroneous, the byte error correction value forming unit 51j outputs the byte error correction value

$$a {( j )}^{cor} = \frac{{s}_{1} {s}_{3} + {s}_{2}^{2}}{{s}_{3} + {α}^{2 j} {s}_{1}} = a ( j )$$

and the byte error correction value forming unit 51k outputs the byte error correction value

$$a {( k )}^{cor} = \frac{{s}_{1} {s}_{3} + {s}_{2}^{2}}{{s}_{3} + {α}^{2 k} {s}_{1}} = a ( k ) .$$

For all other byte error correction value forming units 51r where r≠j,k and 0≤r≤N−1, the byte error correction value is equal to a(r)^{cor}=0.

### Byte Error Correction Value Forming Unit

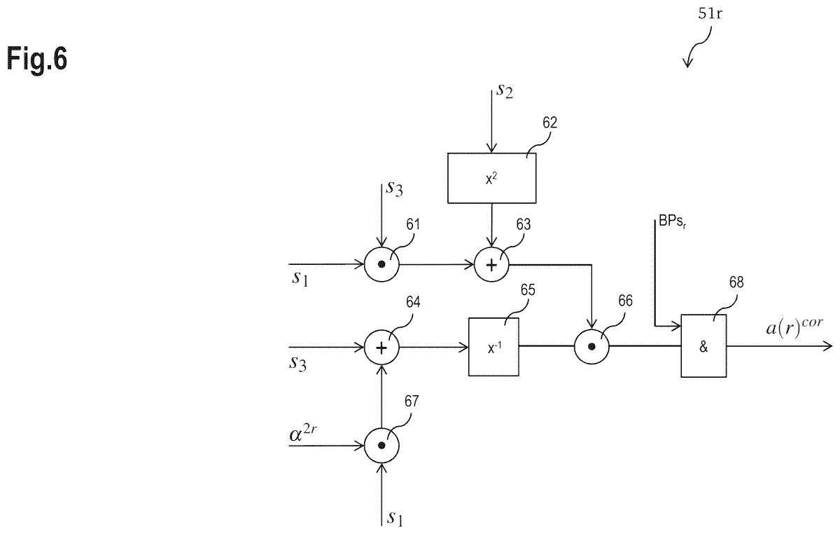

FIG. 6 shows one possible configuration of the byte error correction value forming unit 51r, wherein r can assume a value of 0 to N−1.

The byte error correction value forming unit 51r comprises
two multipliers 61, 66 each having a first and a second m-bit-wide input and an m-bit-wide output,
two XOR circuits 63, 64 each having a first m-bit-wide input, a second m-bit-wide input and an m-bit-wide output,
a constant multiplier 67 having a first and a second m-bit-wide input and an m-bit-wide output, wherein a constant value a^{2r} is present at the second input, a squarer 62 having an m-bit-wide input and an m-bit-wide output,
an inverting circuit 65 having an m-bit-wide input and an m-bit-wide output, and
an AND circuit 68 having a first1-bit-wide input, a second m-bit-wide input and an m-bit-wide output.

The value of the component s₁ is present at the first input of the multiplier 61 and the value of the component ss is present at the second input of the multiplier 61. The multiplier 61 forms the value s₁. Ss in the Galois field GF(2^{m}) and outputs the value s₁· s₃ at its output. The output of the multiplier 61 is connected to the first input of the XOR circuit 63.

The second input of the XOR circuit 63 is connected to the output of the squarer 62, at the input of which the value of the component s₂ is present. Consequently, the squarer 62 outputs the value s₂ at its output. The XOR circuit 63 forms the component-by-component XOR function for the values present at its two inputs and outputs the value s₁s₃+s₂ at its output. The output of the XOR circuit 63 is connected to the first input of the multiplier 66.

The value of the component ss is present at the first input of the XOR circuit 64. The value of the component s₁ is present at the first input of the constant multiplier 67 and the constant a^{2r} is present at the second input of the constant multiplier 67. The constant multiplier 67 realizes the operation a₂ᵣ·s₁ in the Galois field GF(2^{m}). The constant multiplier can be implemented for example using XOR gates.

At the output of the XOR circuit 64, the value s₃+a^{2r} s₁ is provided and passed to the input of the inverter 65. The inverter 65 provides the value

$$\frac{1}{{s}_{3} + {α}^{2 r}}$$

at its output.

The output of the inverter 65 is connected to the first input of the multiplier 66. The multiplier 66 thus provides the value

$$\frac{{s}_{1} {s}_{3} + {s}_{2}^{2}}{{s}_{3} + {α}^{2 r} {s}_{1}} = a ( r )$$

at its output. In this case, a(r) is the byte error correction value for the r-th byte. The value of the byte error position signal BPsᵣ is present at the first input of the AND circuit 68. The second input of the AND circuit 68 is connected to the output of the multiplier 66.

The AND circuit realizes a bit-by-bit ANDing of the m bits present at its two inputs with the byte error position signal BPsᵣ, such that it provides the value

$$\frac{{s}_{1} {s}_{3} + {s}_{2}^{2}}{{s}_{3} + {α}^{2 r} {s}_{1}} \cdot {BPs}_{r} = a ( r ) \cdot {BPs}_{r} = a {( r )}^{cor}$$

at its output.

### Byte Error Correction Value Forming Unit, Alternative Embodiment

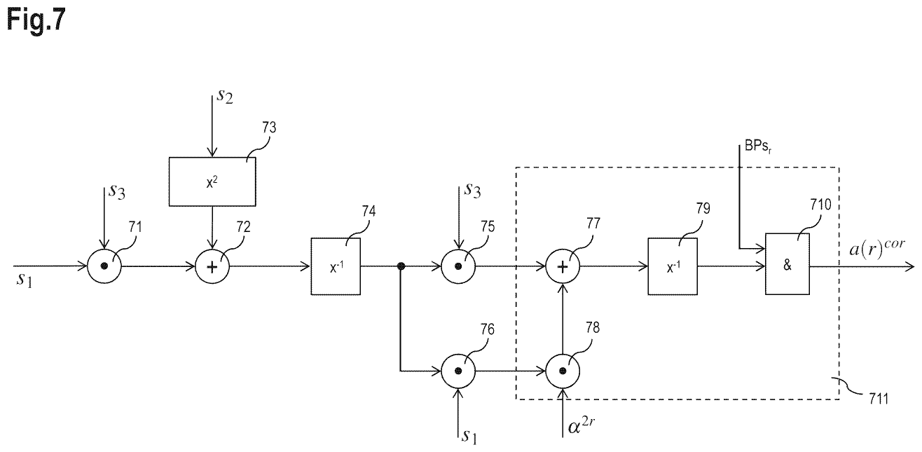

FIG. 7 shows a further possible configuration of the byte error correction value forming unit 51r, which is described for the r-th byte as in FIG. 6, wherein r can assume a value of 0 to (N−1).

The byte error correction value forming unit 51r shown in FIG. 7 comprises
three multipliers 71, 75, 76 each having a first m-bit-wide input, a second m-bit-wide input and an m-bit-wide output,
two XOR circuits 72, 77 each having an m-bit-wide first input, an m-bit-wide second input and an m-bit-wide output,
a constant multiplier 78 having a first m-bit-wide input, a second m-bit-wide input and an m-bit-wide output, wherein a constant value der is present at the second input,
a squarer 73 having an m-bit-wide input and an m-bit-wide output,
two inverters 74, 79 each having an m-bit-wide input and an m-bit-wide output, and
an AND circuit 710 having a first1-bit-wide input, a second m-bit-wide input and an m-bit-wide output.

The value of the component s₁ is present at the first input of the multiplier 71 and the value of the component ss is present at the second input of the multiplier 71. The multiplier 71 forms the value s₁. Ss in the Galois field GF(2^{m}) and provides the value s₁·s₃ at its output. The output of the multiplier 71 is connected to the first input of the XOR circuit 72.

The second input of the XOR circuit 72 is connected to the output of the squarer 73, at the input of which the value of the component s₂ is present. The squarer 73 thus provides the value s₂² at its output. The XOR circuit 72 forms the component-by-component XOR function for the values present at its two inputs and provides the value s₁s₃+s₂ ² at its output. The output of the XOR circuit 72 is connected to the input of the inverter 74. The inverter 74 provides the value

$$\frac{1}{{s}_{1} {s}_{3} + {s}_{2}^{2}}$$

at its output.

The output of the inverter 74 is connected to the first input of the multiplier 75, at the second input of which the value of the component ss is present. Furthermore, the output of the inverter 74 is connected to the first input of the multiplier 76, at the second input of which the value of the component s₁ is present.

The multiplier 76 provides the value

$$\frac{{s}_{1}}{{s}_{1} {s}_{3} + {s}_{2}^{2}}$$

at its output. The output of the multiplier 76 is connected to the first input of the constant multiplier 78. The value a^{2r} is present at the second input of the constant multiplier 78. The constant multiplier 78 provides the value

$$\frac{{α}^{2 r} {s}_{1}}{{s}_{1} {s}_{3} + {s}_{2}^{2}}$$

at its output. The constant multiplier 78 multiplies the value present at its first input by the value of the constant a^{2r} present at its second input in the Galois field GF2^{m}. This multiplication is implemented by corresponding XORings of the bits present at the first input. The constant a^{2r} is uniquely assigned to the r-th byte.

The multiplier 75 provides the value

$$\frac{{s}_{3}}{{s}_{1} {s}_{3} + {s}_{2}^{2}}$$

at its output. The output of the multiplier 75 is connected to the first input of the XOR circuit 77.

The output of the constant multiplier 78 is connected to the second input of the XOR circuit 77. The XOR circuit 77 provides the value

$$\frac{{α}^{2 r} {s}_{1}}{{s}_{1} {s}_{3} + {s}_{2}^{2}} + \frac{{s}_{3}}{{s}_{1} {s}_{3} + {s}_{2}^{2}} + \frac{{α}^{2 r} {s}_{1} + {s}_{3}}{{s}_{1} {s}_{3} + {s}_{2}^{2}}$$

at its output. The output of the XOR circuit 77 is connected to the input of the inverter 79.

The inverter 79 provides the value

$$\frac{{s}_{1} {s}_{3} + {s}_{2}^{2}}{{α}^{2 r} {s}_{1} + {s}_{3}}$$

at its output. The output of the inverter 79 is connected to the second input of the AND circuit 710.

The value of the byte error position signal BPsᵣ is present at the first input of the AND circuit 710. The AND circuit 710 realizes a bit-by-bit ANDing of the m bits present at its second input with the byte error position signal BPsᵣ. The AND circuit 710 thus provides the value

$$\frac{{s}_{1} {s}_{3} + {s}_{2}^{2}}{{s}_{3} + {α}^{2 r} {s}_{1}} \cdot {BPs}_{r} = a ( r ) \cdot {BPS}_{r} = a {( r )}^{cor}$$

at its output.

The part shown in FIG. 7 comprising the multipliers 71, 75, 76, the XOR circuit 72 and the squarer 73 outputs the values

$$\frac{{s}_{3}}{{s}_{1} {s}_{3} + {s}_{2}^{2}}$$

$$and$$

$$\frac{{s}_{1}}{{s}_{1} {s}_{3} + {s}_{2}^{2}}$$

at the outputs of the multipliers 75 and 76, which values are determined solely by the values of the components s₁, s₂, Ss and are independent of the byte position r. This part of the circuit is identical for all the byte error correction value forming units 510, 511, . . . , 51N−1 shown in FIG. 5. It is thus possible to provide this circuit part only once and to utilize the output signals of the multipliers 71, 75 and 76 for all the byte error correction value forming units 510 to 51N−1. For the different byte positions 0 to N−1, it is then only necessary to realize in each case the remaining part 711 of the circuit as shown in FIG. 7, comprising the XOR circuit 77, the constant multiplier 78, the inverter 79 and the AND circuit 710.

One option is to realize a byte error correction value forming unit for correctable byte positions, for example for all correctable byte positions or for some of the correctable byte positions using at most three multiplications. In this case, the three multiplications can be implemented using three multipliers. Moreover, one option is to carry out in particular further multiplications by a constant by using constant multipliers.

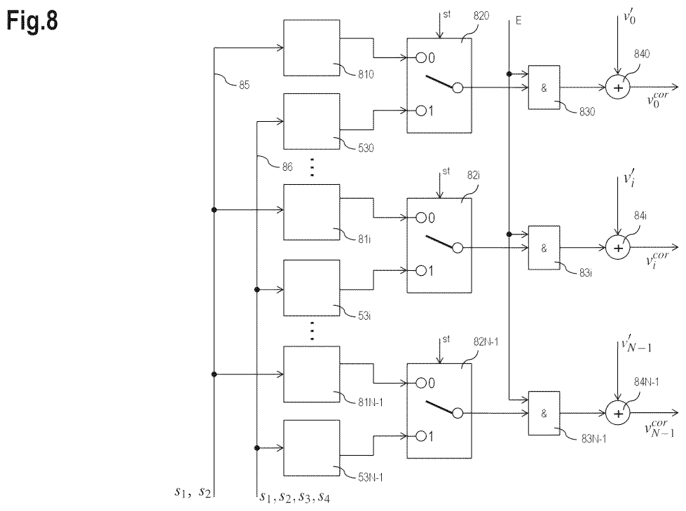

### Correction of Both 1-Byte and 2-Byte Errors, FIG. 8

FIG. 8 shows one exemplary circuit for correcting 1-byte errors and 2-byte errors, wherein the circuits can be used for determining byte error position signals for 2-byte errors and for correcting 2-byte errors.

The circuit shown in FIG. 8 is configured for example in such a way that
a 2-byte error is corrected if a 2-byte error is present,
a 1-byte error is corrected if a 1-byte error is present, and
no correction is carried out if no error is present.

For this purpose, FIG. 8 comprises
N byte error correction value forming units 810, . . . , 81i, . . . , 81N−1 for correcting 1-byte errors, each having a 2·m-bit-wide input for inputting the components s₁, s₂ and an m-bit-wide output for outputting an m-bit-wide byte error correction value,
N byte correctors 530, . . . , 53i, . . . , 53N−1 for correcting 2-byte errors, each having a 4·m-bit-wide input for inputting the components s₁, s₂, s₃, s₄ and an m-bit-wide output for outputting an m-bit-wide byte error correction value, as described in FIG. 5,
N multiplexers 820, . . . , 82i, . . . , 82N−1, each having
a first m-bit-wide input (0-input),
a second m-bit-wide input (1-input),
a 1-bit-wide control input, to which a binary control signal st can be applied, and
an m-bit-wide output,
N AND circuits 830, . . . , 83i, . . . , 83N−1, each having a first1-bit-wide input for inputting a binary error signal E, a second m-bit-wide input and an m-bit-wide output, and
N XOR circuits 840, . . . , 84i, . . . , 84N−1, each having a first m-bit-wide input, a second m-bit-wide input and an m-bit-wide output.

A line 85 carries the components s₁, s₂ and is connected to the respective input of the byte error correction value forming units 810, . . . , 81i, . . . , 81N−1.

A line 86 carries the components s₁, s₂, s₃, s₄ and is connected to the respective input of the byte correctors 530, . . . , 53i, . . . , 53N−1.

In the case of a 1-byte error in the byte position 0, the byte error correction value forming unit 810 provides the correct byte error correction value for the erroneous 0-th byte v′₀ at its output. This correspondingly applies to the further byte error correction value forming units. In this regard, in the case of a 1-byte error in the byte position i, the byte error correction value forming unit 81i provides the correct byte error correction value for the erroneous i-th byte v′ at its output. In the case of a 1-byte error in the byte position (N−1), the byte error correction value forming unit 81N−1 provides the correct byte error correction value for the erroneous (N−1)-th byte v′_{N-1} at its output.

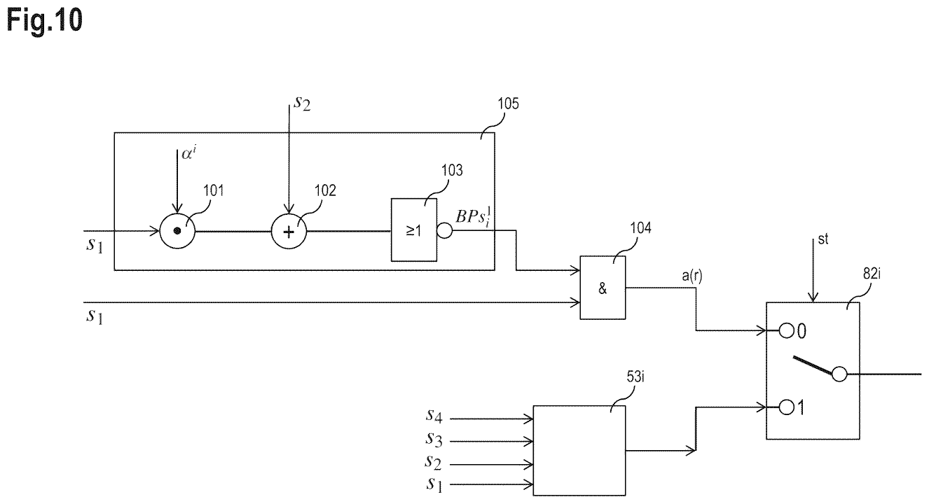

One possible realization of a byte error correction value forming unit for correcting a 1-byte error is explained in association with FIG. 10.

With regard to one possible realization of the byte correctors 530 to 53N−1, reference should be made for example to the byte error position signal forming units described in association with FIG. 2 and the byte error correction value forming units described in association with FIG. 6 and FIG. 7.

The output of the byte error correction value forming unit 810 is connected to the first input of the multiplexer 820. The output of the byte corrector 530 is connected to the second input of the multiplexer 820. If the value of the control signal st is equal to 0, then the multiplexer 820 connects its 0-input (the first input) to its output. If the value of the control signal st is equal to 1, then the multiplexer 820 connects its 1-input (the second input) to its output.

The binary error signal E is present at the first input of the AND circuit 830. The output of the multiplexer 820 is connected to the second input of the AND circuit 830. The output of the AND circuit 830 is connected to the first input of the XOR circuit 840. The possibly erroneous byte v′ is present at the second input of the XOR circuit 840. The XOR circuit 840 provides the corrected byte value v₀^{cCor} at its output.

The AND circuit 830 enables a component-by-component ANDing of the m-digit value present at its second input with the error signal E. If the error signal E=0, the AND circuit 830 outputs the m-component value 0. If the error signal E=1, the AND circuit 830 outputs the value present at its second input.

These explanations correspondingly apply to the remaining byte positions.

The output of the byte error correction value forming unit 81i is connected to the first input of the multiplexer 82i. The output of the byte error correction value forming unit 53i is connected to the second input of the multiplexer 82i. If the value of the control signal st is equal to 0, then the multiplexer 82i connects its 0-input (the first input) to its output. If the value of the control signal st is equal to 1, then the multiplexer 82i connects its 1-input (the second input) to its output.

The binary error signal E is present at the first input of the AND circuit 83i. The output of the multiplexer 82i is connected to the second input of the AND circuit 83i. The output of the AND circuit 83i is connected to the first input of the XOR circuit 84i. The possibly erroneous byte v′ᵢ is present at the second input of the XOR circuit 84i. The XOR circuit 84i provides the corrected byte value vᵢ^{cor} at its output.

The AND circuit 83i enables a component-by-component ANDing of the m-digit value present at its second input with the error signal E. If the error signal E=0, the AND circuit 83i outputs the m-component value 0. If the error signal E=1, the AND circuit 83i outputs the value present at its second input.

The output of the byte error correction value forming unit 81N−1 is connected to the first input of the multiplexer 82N−1. The output of the byte error correction value forming unit 53N−1 is connected to the second input of the multiplexer 82N−1. If the value of the control signal st is equal to 0, then the multiplexer 82N−1 connects its 0-input (the first input) to its output. If the value of the control signal st is equal to 1, then the multiplexer 82N−1 connects its 1-input (the second input) to its output.

The binary error signal E is present at the first input of the AND circuit 83N−1. The output of the multiplexer 82N−1 is connected to the second input of the AND circuit 83N−1. The output of the AND circuit 83N−1 is connected to the first input of the XOR circuit 84N−1. The possibly erroneous byte vy-1 is present at the second input of the XOR circuit 84N−1. The XOR circuit 84N−1 provides the corrected byte value v²¹ at its output.

The AND circuit 83N−1 enables a component-by-component ANDing of the m-digit value present at its second input with the error signal E. If the error signal E=0, the AND circuit 83N−1 outputs the m-component value 0. If the error signal E=1, the AND circuit 83N−1 outputs the value present at its second input.

The error signal E assumes
the value 1 if a 1-byte error or a 2-byte error has occurred or
the value 0 if no error has occurred.

The control signal st assumes
the value 0 if a 1-byte error has occurred and
the value 1 if a 2-byte error has occurred.
   Circuit for Correcting More than Two Byte Errors

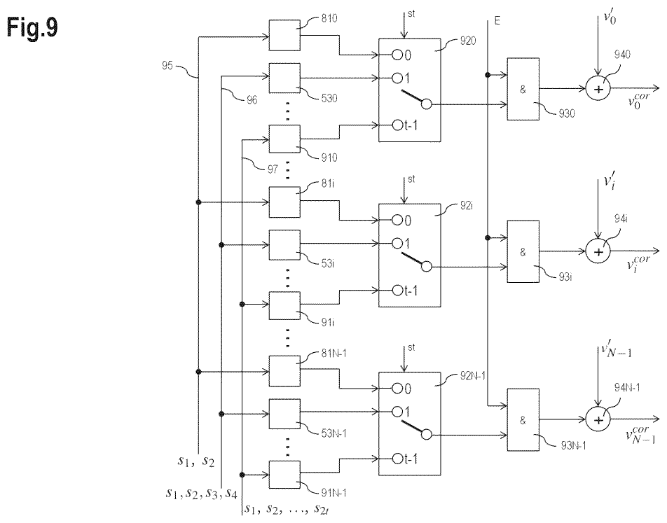

FIG. 9 shows a circuit for correcting 1-byte errors, 2-byte errors up to t-byte errors. The elements described in FIG. 8 can correspondingly be used in this circuit. The circuit shown in FIG. 9 makes it possible that
a 1-byte error is corrected if a 1-byte error is present,
a 2-byte error is corrected if a 2-byte error is present, . . .
a t-byte error is corrected if a t-byte error is present, and
no correction is carried out if no error is present.

By way of example, the case is described in which a t-byte-error-correcting and (t+1)-byte-error-detecting code is utilized, wherein in particular t>2 holds true.

The circuit in accordance with FIG. 9 comprises
the N byte error correction value forming units 810 to 81N−1 in accordance with FIG. 8,
the N byte correctors 530 to 53N−1 in accordance with FIG. 8 (as also described in FIG. 5), up to
N byte error correction value forming units 910, . . . , 91i, . . . , 91N−1 for correcting t-byte errors, each having a 2·t·m-bit-wide input for inputting the components s₁, s₂, . . . , s₂t and an m-bit-wide output for outputting an m-bit-wide byte error correction value,
N multiplexers 920, . . . , 92i, . . . , 92N−1, each having
a first m-bit-wide input (0-input),
a second m-bit-wide input (1-input),
up to a t-th m-bit-wide input ((t-1)-input),
a control input, at which a control signal st is present, which can assume t different values, and
an m-bit-wide output.
N AND circuits 930, . . . , 93i, . . . , 93N−1, each having a first1-bit-wide input for inputting a binary error signal E, a second m-bit-wide input and an m-bit-wide output, and
N XOR circuits 940, . . . , 94i, . . . , 94N−1, each having a first m-bit-wide input, a second m-bit-wide input and an m-bit-wide output.

The 0-input of one of the multiplexers 920 to 92N−1 is connected to the output thereof if the control signal st has the value 0. Accordingly, a connection of one of the inputs 0 to (t-1) to the output can be produced by virtue of the corresponding control signal st assuming a value of between 0 and (t-1). If st=(t-1)=3 holds true, for example, then the third input (2-input) of the multiplexer is connected to the output thereof.

A line 95 carries the components s₁, s₂ and is connected to the respective input of the byte error correction value forming units 810, . . . , 81i, . . . , 81N−1.

A line 96 carries the components s₁, s₂, s₃, s₄ and is connected to the respective input of the byte correctors 530, . . . , 53i, . . . , 53N−1.

Finally, a line 97 is shown, with the aid of which the components s₁, s₂, . . . , s₂t are passed to the respective input of the byte error correction value forming units 910, . . . , 91i, . . . , 91N−1.

In the case of a 1-byte error in the byte position 0, the byte error correction value forming unit 810 provides the correct byte error correction value for the erroneous 0-th byte v′₀ at its output. This correspondingly applies to the further byte error correction value forming units. In this regard, in the case of a 1-byte error in the byte position i, the byte error correction value forming unit 81i provides the correct byte error correction value for the erroneous i-th byte v′ᵢ at its output. In the case of a 1-byte error in the byte position (N−1), the byte error correction value forming unit 81N−1 provides the correct byte error correction value for the erroneous (N−1)-th byte v′_{N-1} at its output.

In the case of a 2-byte error, the byte corrector 530 provides the correct byte error correction value for the erroneous 0-th byte v′₀ at its output. This correspondingly applies to the further byte error correction value forming units. In this regard, in the case of a 2-byte error, the byte error correction value forming unit 53i provides the correct byte error correction value for the erroneous i-th byte v′ᵢ at its output. In the case of a 2-byte error, the byte error correction value forming unit 53N−1 provides the correct byte error correction value for the erroneous (N−1)-th byte v′N−1 at its output.

In the case of a t-byte error, the byte error correction value forming unit 910 provides the correct byte error correction value for the erroneous 0-th byte v′ at its output. This correspondingly applies to the further byte error correction value forming units. In this regard, in the case of a t-byte error, the byte error correction value forming unit 91i provides the correct byte error correction value for the erroneous i-th byte v′ at its output. In the case of a t-byte error, the byte error correction value forming unit 91N−1 provides the correct byte error correction value for the erroneous (N−1)-th byte v′_{N-1} at its output.

For non-erroneous bytes, the byte error correction values assigned to these byte positions are in each case masked with the value 0.

The output of the byte error correction value forming unit 810 is connected to the first input (0-input) of the multiplexer 920. The output of the byte corrector 530 is connected to the second input (1-input) of the multiplexer 920. Correspondingly, the output of the byte error correction value forming unit 910 is connected to the t-th input ((t-1)-input) of the multiplexer 920.

The binary error signal E is present at the first input of the AND circuit 930. The output of the multiplexer 920 is connected to the second input of the AND circuit 930. The output of the AND circuit 930 is connected to the first input of the XOR circuit 940. The possibly erroneous byte v′ is present at the second input of the XOR circuit 940. The XOR circuit 940 provides the corrected byte value vCor at its output.

The AND circuit 930 enables a component-by-component ANDing of the m-digit value present at its second input with the error signal E. If the error signal E=0, the AND circuit 930 outputs the m-component value 0. If the error signal E=1, the AND circuit 930 outputs the value present at its second input.

These explanations correspondingly apply to the remaining byte positions.

The output of the byte error correction value forming unit 81i is connected to the first input (0-input) of the multiplexer 92i. The output of the byte error correction value forming unit 53i is connected to the second input (1-input) of the multiplexer 92i. Correspondingly, the output of the byte error correction value forming unit 91i is connected to the t-th input ((t-1)-input) of the multiplexer 92i.

The binary error signal E is present at the first input of the AND circuit 93i. The output of the multiplexer 92i is connected to the second input of the AND circuit 93i. The output of the AND circuit 93i is connected to the first input of the XOR circuit 94i. The possibly erroneous byte v′ᵢ is present at the second input of the XOR circuit 94i. The XOR circuit 94i provides the corrected byte value vᵢ^{cor} at its output.

The AND circuit 93i enables a component-by-component ANDing of the m-digit value present at its second input with the error signal E. If the error signal E=0, the AND circuit 93i outputs the m-component value 0. If the error signal E=1, the AND circuit 93i outputs the value present at its second input.

The output of the byte error correction value forming unit 81N−1 is connected to the first input (0-input) of the multiplexer 92N−1. The output of the byte error correction value forming unit 53N−1 is connected to the second input (1-input) of the multiplexer 92N-1. Correspondingly, the output of the byte error correction value forming unit 91N−1 is connected to the t-th input ((t-1)-input) of the multiplexer 92N−1.

The binary error signal E is present at the first input of the AND circuit 93N−1. The output of the multiplexer 92N−1 is connected to the second input of the AND circuit 93N−1. The output of the AND circuit 93N−1 is connected to the first input of the XOR circuit 94N−1. The possibly erroneous byte v′_{N-1} is present at the second input of the XOR circuit 94N−1. The XOR circuit 94N−1 provides the corrected byte value v_{N-1}^{cor} at its output.

The AND circuit 93N−1 enables a component-by-component ANDing of the m-digit value present at its second input with the error signal E. If the error signal E=0, the AND circuit 93N−1 outputs the m-component value 0. If the error signal E=1, the AND circuit 93N−1 outputs the value present at its second input.

The error signal E assumes
the value 1 if a 1-byte error or a 2-byte error, . . . or a t-byte error has occurred or
the value 0 if no error has occurred.

The control signal st assumes
the value 0 if a 1-byte error has occurred,
the value 1 if a 2-byte error has occurred,
etc.
the value (t-1) if a t-byte error has occurred.

### Byte Error Corrector for 1-Byte Errors

FIG. 10 shows one exemplary circuit for a byte error correction value forming unit 81i for the i-th byte, such as was explained e.g. with reference to FIG. 8.

The byte error correction value forming unit 81i comprises
a constant multiplier 101 having
a first m-bit-wide input,
a second m-bit-wide input, at which the constant value aⁱ is present, and
an m-bit-wide output,
an XOR circuit 102 having a first m-bit-wide input, a second m-bit-wide input and an m-bit-wide output,
a NOR circuit 103 having an m-bit-wide input and a 1-bit-wide output,
an AND circuit 104 having a first1-bit-wide input, a second m-bit-wide input and an m-bit-wide output.

Furthermore, FIG. 10 shows the multiplexer 82i and the byte error correction value forming unit 53i from FIG. 8 (and FIG. 5).

The constant multiplier 101, the XOR circuit 102 and the NOR circuit 103 form a byte error position signal forming unit 105 and serve for example for forming the byte error position signal BPs₁, which indicates whether a 1-byte error is present in the i-th byte position.

At the output of the AND circuit 104, the m-dimensional byte error correction value a(i)^{cor} is provided if a 1-byte error has occurred in the byte position i. If the 1-byte error has occurred in another byte position j different than i, the byte error position signal BPsᵢ=0 and the value 0 is thus also present at the output of the AND circuit 104.

The component s₁ is present at the first input of the constant multiplier 101 and a constant a^{L} is present at the second input of the constant multiplier 101. The output of the constant multiplier 101 is connected to the first input of the XOR circuit 102. The component s₂ is present at the second input of the XOR circuit 102. The output of the XOR circuit 102 is connected to the input of the NOR circuit 103. The output of the NOR circuit 103 is connected to the first input of the AND circuit 104. The component s₁ is present at the second input of the AND circuit 104. The output of the AND circuit 104 is connected to the first input of the multiplexer 82i.

The second input of the multiplexer 82i is connected to the output of the byte error correction value forming unit 53i.

Consequently, the byte error correction value for a 1-byte error is provided at the first input of the multiplexer 82i and the byte error correction value for a 2-byte error is provided at the second input of the multiplexer 82i.

Correspondingly, the control signal st for the multiplexer 82i is
equal to 0 if a 1-byte error is present, in order to connect the first input (0-input) of the multiplexer 82i to the output thereof, or
equal to 1 if a 2-byte error is present, in order to connect the second input (1-input) of the multiplexer 82i to the output thereof.

If no error is present, the value of the control signal st is arbitrary. It can be fixed at 0, for example, as is described by way of example below.

If no error is present, the value of the error signal E is equal to 0. This was explained above in association with FIG. 8. On the basis of the AND circuit 83i connected downstream, which logically ANDs the signal at the output of the multiplexer 82i component by component with the error signal E, it is ensured that in the case of an error signal E=0 (that is to say if no error is present) the value 0 is provided at the output of the AND circuit 83i, to be precise independently of the signal at the output of the multiplexer 82i. Consequently, no correction of the i-th byte is carried out.

### Circuit for Determining an Error Signal

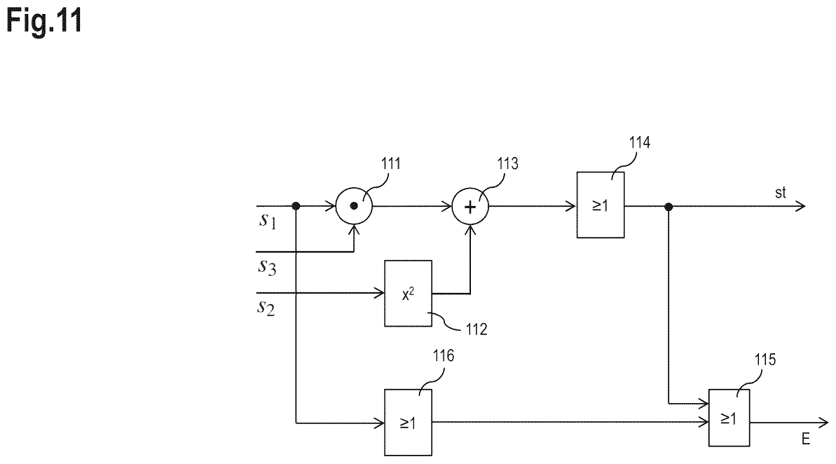

FIG. 11 shows one exemplary circuit for determining the error signal E such as is utilized for example in the circuit shown in FIG. 8.

The arrangement shown in FIG. 11 comprises
a multiplier 111 having a first m-bit-wide input, a second m-bit-wide input and an m-bit-wide output,
an XOR circuit 113 having a first m-bit-wide input, a second m-bit-wide input and an m-bit-wide output,
a squarer 112 having an m-bit-wide input and an m-bit-wide output,
an OR circuit 114 having an m-bit-wide input and a 1-bit-wide output,
an OR circuit 116 having an m-bit-wide input and a 1-bit-wide output, and
an OR circuit 115 having a first binary input, a second binary input and having a binary output.

The value of the component s₁ is present at the first input of the multiplier 111. The value of the component ss is present at the second input of the multiplier 111. The output of the multiplier 111 is connected to the first input of the XOR circuit 113.

The component s₁ is also present at the input of the OR circuit 116. The output of the OR circuit 116 is connected to the second input of the OR circuit 115.

The component s₂ is present at the input of the squarer 112. The output of the squarer 112 is connected to the second input of the XOR circuit 113.

The output of the XOR circuit 113 is connected to the input of the OR circuit 114 and the output of the OR circuit 114 is connected to the first input of the OR circuit 115.

The control signal st is provided at the output of the OR circuit 114 and the error signal E is provided at the output of the OR circuit 115.

The control signal st assumes the value 0 if the following holds true:

$${s}_{1} {s}_{3} + {s}_{2}^{2} = 0.$$

Correspondingly, the control signal st assumes the value 1 if the following holds true:

$${s}_{1} {s}_{3} + {s}_{2}^{2} \neq 0.$$

The error signal E assumes the value 0 if the control signal st is equal to 0 and if the value of the component s₁ is equal to 0. In this case, neither a 1-byte error nor a 2-byte error is present.

If the value of the control signal st is equal to 1, a 2-byte correction using the byte correctors 530 to 53N−1 is carried out in the circuit in accordance with FIG. 8.

If the value of the control signal st is equal to 0, firstly a 1-byte correction using the byte error correction value forming units 810 to 81N−1 is carried out in the circuit in accordance with FIG. 8. If the error signal E is also equal to 0, such that neither a 1-byte error nor a 2-byte error is present, the AND circuits 830 to 83N−1 all output the value 0, such that no correction of the bytes v′₀ to v′_{N-1} is carried out.

If a 3-byte error is detected, the error correction can be terminated, for example. Such a termination of the error correction can be carried out at the system level.

### Circuit for Detecting a 3-Byte Error

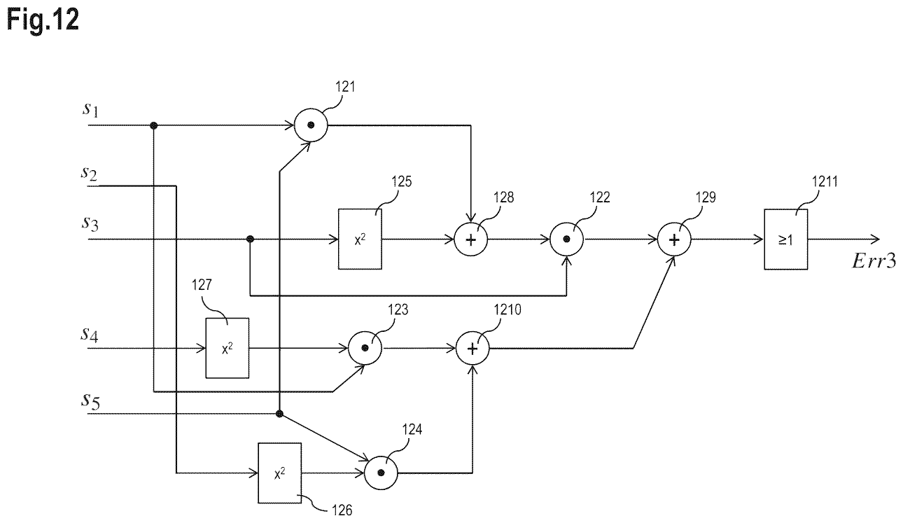

FIG. 12 shows one exemplary circuit for detecting a 3-byte error. For this purpose, the circuit comprises
four multipliers 121, 122, 123, 124, each having a first m-bit-wide input, a second m-bit-wide input and an m-bit-wide output,
three squarers 125, 126, 127, each having an m-bit-wide input and an m-bit-wide output,
three XOR circuits 128, 129, 1210, each having a first m-bit-wide input, a second m-bit-wide input and an m-bit-wide output, and
an OR circuit 1211 having an m-bit-wide input and a binary output, wherein the OR circuit 1211 carries out a component-by-component ORing of the m bits present at its input.

The value of the component s₁ is present at the first input of the multiplier 121 and at the second input of the multiplier 123.

The value of the component s₂ is present at the input of the squarer 126.

The value of the component s₃ is present at the input of the squarer 125 and at the second input of the multiplier 122.

The value of the component s is present at the input of the squarer 127.

The value of the component s₅ is present at the second input of the multiplier 121 and at the first input of the multiplier 124.

The output of the multiplier 121 is connected to the first input of the XOR circuit 128. The output of the squarer 125 is connected to the second input of the XOR circuit 128. The output of the XOR circuit 128 is connected to the first input of the multiplier 122. The output of the multiplier 122 is connected to the first input of the XOR circuit 129.

The output of the squarer 127 is connected to the first input of the multiplier 123. The output of the multiplier 123 is connected to the first input of the XOR circuit 1210.

The output of the squarer 126 is connected to the second input of the multiplier 124 and the output of the multiplier 124 is connected to the second input of the XOR circuit 1210. The output of the XOR circuit 1210 is connected to the second input of the XOR circuit 129. The output of the XOR circuit 129 is connected to the input of the OR circuit 1211 and a signal Err3 is available at the output of the OR circuit 1211, on the basis of which signal a 3-byte error can be determined.

The signal Err3 assumes the value 1 if the following holds true:

$$( {s}_{1} {s}_{5} + {s}_{3}^{2} ) \cdot {s}_{3} + {s}_{2}^{2} {s}_{5} + {s}_{4}^{2} {s}_{1} = {s}_{1} {s}_{3} {s}_{5} + {s}_{3}^{3} + {s}_{2}^{2} {s}_{5} + {s}_{4}^{2} {s}_{1} \neq 0.$$

Correspondingly, the signal Err3 assumes the value 0 if the following holds true:

$$( {s}_{1} {s}_{5} + {s}_{3}^{2} ) \cdot {s}_{3} + {s}_{2}^{2} {s}_{5} + {s}_{4}^{2} {s}_{1} = 0.$$

### Alternative Determination of Byte Error Correction Values

An alternative, efficient variant for determining byte error correction values is described below.

By way of example, the correction of 2-byte errors is considered.

The byte error correction value a(k) for the k-th byte position is determined in accordance with equation (50) as

$$a ( k ) = \frac{{s}_{1} {s}_{3} + {s}_{2}^{2}}{{s}_{3} + {α}^{2 k} {s}_{1}}$$

Thus, for each byte position k that is to be corrected, the value

$${s}_{1} {s}_{3} + {s}_{2}^{2}$$

determined from the syndrome components s₁, s₂, s₃ is to be divided by

$${s}_{3} + {α}^{2 k} {s}_{1}$$

in the Galois field GF(2^{m}). This divisor depends on the byte position k and is different for each byte position. A separate division is therefore required for each byte position.

This division can be implemented for example by first forming the inverse value

$$\frac{1}{{s}_{3} + {α}^{2 k} {s}_{1}}$$

of the divisor using an inverter in the Galois field GF(2^{m}), which value is then multiplied by the term s₁s3+s₂² using a multiplier.

By way of example, one inverter and one multiplier are needed for each byte position that is to be corrected.

A reduction in realization effort can be achieved by first determining, instead of a(k),

$$\frac{1}{a ( k )} = \frac{{s}_{3} + {α}^{2 k} {s}_{1}}{{s}_{1} {s}_{3} + {s}_{2}^{2}} = \frac{{s}_{3}}{{s}_{1} {s}_{3} + {s}_{2}^{2}} + \frac{{s}_{1}}{{s}_{1} {s}_{3} + {s}_{2}^{2}} \cdot {α}^{2 k}$$

Inversion yields

$$a ( k ) = \frac{1}{\frac{1}{a ( k )}} = \frac{1}{\frac{{s}_{3}}{{s}_{1} {s}_{3} + {s}_{2}^{2}} + \frac{{s}_{1}}{{s}_{1} {s}_{3} + {s}_{2}^{2}} \cdot {α}^{2 k}} .$$

In this case, the term

$$\frac{{s}_{3}}{{s}_{1} {s}_{3} + {s}_{2}^{2}}$$

and the term

$$\frac{{s}_{1}}{{s}_{1} {s}_{3} + {s}_{2}^{2}}$$

can be formed centrally and provided for all byte positions that are to be corrected.

For the k-th byte position, the term

$$\frac{{s}_{1}}{{s}_{1} {s}_{3} + {s}_{2}^{2}}$$

can be multiplied by a^{2k}. For each byte position, this multiplication is a multiplication by a constant corresponding to the byte position.

An inverter in the Galois field GF(2^{m}) is used to determine the inverse value of

$$\frac{{s}_{3}}{{s}_{1} {s}_{3} + {s}_{2}^{2}} + \frac{{s}_{1}}{{s}_{1} {s}_{3} + {s}_{2}^{2}} \cdot {α}^{2 k}$$

in parallel or at least to some extent in parallel or at least to some extent simultaneously (that is to say in part at overlapping times). In this case, k assumes all values for which byte positions are corrected in the event of a byte error. A disadvantage in this case is that each byte position to be corrected requires an inverter in the Galois field GF(2^{m}) for the (at least to some extent) parallel processing.

The text below provides an illustrative explanation, on the basis of the correction of 2-byte errors, of how the byte error correction values can be efficiently determined.

It is advantageous in this case that the coefficients of a locator polynomial are symmetrical functions of the erroneous byte positions and can be determined as functions of components of the error syndrome by solving a linear equation system.

In the event of a 2-byte error in the byte positions aⁱ and a^{j}, the coefficients of the locator polynomial

$${L}_{2} ( x ) = {x}^{2} + x \cdot {σ}_{1} + {σ}_{2} = ( x + {α}^{i} ) ( x + {α}^{j} )$$

are determined as

$${σ}_{1} = {α}^{i} + {α}^{j} and {σ}_{2} = {α}^{i} \cdot {α}^{j}$$

Here, σ₁ and σ₂ are symmetrical functions of the byte positions aⁱ and a^{j}, σ₁ being the coefficient of the linear element x of the locator polynomial La(x) and being the sum of aⁱ and a^{j}.

Between the syndrome components s₁, s₂, s₃, s₄ and the coefficients σ₁ and σ₂ of the locator polynomial there exists the relationship

$$( \begin{matrix}{s}_{1} & {s}_{2} \\ {s}_{2} & {s}_{3}\end{matrix} ) \cdot ( \begin{matrix}{σ}_{2} \\ {σ}_{1}\end{matrix} ) = ( \begin{matrix}{s}_{3} \\ {s}_{4}\end{matrix} ) . \qquad ( 81 )$$

This can be verified by inserting the values

$${s}_{1} = a + b , \\ {s}_{2} = {α}^{i} a + {α}^{j} b , \\ {s}_{3} = {α}^{2 i} a + {α}^{2 j} b , \\ {s}_{4} = {α}^{3 i} a + {α}^{3 j} b , \\ {σ}_{1} = {α}^{i} + {α}^{j} , \\ {σ}_{2} = {α}^{i} \cdot {α}^{j}$$

Equation (81) is a linear equation system that permits the coefficients σ₁ and σ₂, as functions of the syndrome components s₁, s₂, s₃, s₄ to be determined as

$${σ}_{1} = \frac{{s}_{2} {s}_{3} + {s}_{1} {s}_{4}}{{s}_{1} {s}_{3} + {s}_{2}^{2}} \\ and \\ {σ}_{2} = \frac{{s}_{2} {s}_{4} + {s}_{3}^{1}}{{s}_{1} {s}_{3} + {s}_{2}^{2}}$$

In the case of a 2-byte error, for example, the byte error correction values can advantageously be determined on the basis of the coefficient σ₁ of the linear element of the locator polynomial L₂(x) in such a way that a simple realization of the determination of the byte error correction values results.

To correct byte positions that might need to be considered, a potential byte error correction value is determined for erroneous byte positions and non-erroneous byte positions. If there is a 2-byte error and one byte position is erroneous, the byte error correction value can be used to make a correction for this byte position. If a byte position is not erroneous, then the byte error correction value for this byte position can assume any value.

In this regard, it will be noted that the term “erroneous” assumes that an error has been detected for the byte position. Moreover, there is the possibility of there being an error that cannot be detected and therefore also cannot be corrected. This case is not covered by the term “erroneous” in the present context. The same applies when the term “not erroneous” is mentioned herein.

The locator polynomial L₂(x) is used to determine a byte error position signal for the erroneous and non-erroneous byte positions. The byte error position signal for the byte position aⁱ assumes a first value if L₂(aⁱ)=0 and the byte is erroneous, and it assumes a second value, different than the first value, if L₂(aⁱ)≠0 and the byte is not erroneous.

If the byte at the byte position aⁱ is erroneous and it therefore holds true that L₂(aⁱ)=0, then the potential byte error correction value determined for this byte position is used for correction for this byte detected as erroneous. If the byte at the byte position aⁱ is not erroneous and it therefore holds true that L₂(aⁱ)≠0, then the potential byte error correction value determined for this byte position is not used for correction.

The byte error position signal determined for the respective byte position can therefore be used to determine whether or not the potential byte error value determined for this byte position is used for correction.

By way of example, a Reed-Solomon code is used in the Galois field GF(2^{m}) with four syndrome components s₁, s₂, s₃, s₄.

As in equations (3) and (4), an H matrix the first row of which is a⁰, a⁰, . . . a⁰ is initially used. The H matrices H_{Byte} used in equations (3) and (4) have 3 rows and 5 rows.

The H matrix H of the Reed-Solomon code as used by way of illustration in this section has 4 rows:

$$H = ( \begin{matrix}{α}^{0} & {α}^{0} & … & {α}^{0} & … & {α}^{0} \\ {α}^{0} & {α}^{1} & … & {α}^{i} & … & {α}^{n - 1} \\ {α}^{0} & {α}^{2} & … & {α}^{2 \cdot i} & … & {α}^{2 \cdot [ n - 1 ]} \\ {α}^{0} & {α}^{3} & … & {α}^{3 \cdot i} & … & {α}^{3 \cdot [ n - 1 ]}\end{matrix} ) \qquad ( 82 )$$

The H matrix H in accordance with equation (82) is obtained from the H matrix H_{Byte} in accordance with equation (4) as a result of the last row being deleted.

If there is a 2-byte error having the byte error values a and b at the byte positions i and j, the syndrome components s₁, s₂, s₃, s₄ in accordance with equation (6) are obtained as

$${s}_{1} = a + b \\ {s}_{2} = {α}^{i} a + {α}^{j} b \\ {s}_{3} = {α}^{2 i} a + {α}^{2 j} b \\ {s}_{4} = {α}^{3 i} a + {α}^{3 j} b \qquad ( 83 )$$

A locator polynomial L₂(x) in the form

$${L}_{2} ( x ) = {x}^{2} + {σ}_{1} x + {σ}_{2} \qquad ( 84 )$$

where

$${σ}_{1} = \frac{{s}_{1} {s}_{4} + {s}_{2} {s}_{3}}{{s}_{1} {s}_{3} + {s}_{2}^{2}} and {σ}_{2} = \frac{{s}_{2} {s}_{4} + {s}_{3}^{2}}{{s}_{1} {s}_{3} + {s}_{2}^{2}} \qquad ( 85 )$$

is determined for example as a result of the left-hand side of equation (48) being divided by another expression, so that

$${L}_{2} ( x ) = \frac{L ( x )}{{s}_{1} {s}_{3} + {s}_{2}^{2}} \qquad ( 86 )$$

holds true.

If there is a 2-byte error at the byte positions i and j having the byte error values a and b, then the syndrome components s₁ to sa are determined in accordance with equation (83). With the syndrome components s₁ to s₄ it holds that:

$$\begin{matrix}{s}_{1} \cdot {s}_{4} + {s}_{2} \cdot {s}_{3} = ( a + b ) ( {α}^{3 i} a + {α}^{3 j} b ) + ( {α}^{i} a + {α}^{j} b ) ( {α}^{2 i} a + {α}^{2 j} b ) = \\ = {α}^{3 i} {a}^{2} + {α}^{3 i} ab + {α}^{3 j} ab + {α}^{3 j} {b}^{2} + \\ + {α}^{3 i} {a}^{2} + {α}^{2 i} {α}^{j} ab + {α}^{i} {α}^{2 j} ab + {α}^{3 j} {b}^{2} = \\ = ab ( {α}^{3 i} + {α}^{3 j} + {α}^{i} {α}^{2 j} + {α}^{j} {α}^{2 i} )\end{matrix}$$

$$and$$

$$\begin{matrix}{s}_{1} {s}_{3} + {s}_{2}^{2} = ( a + b ) ( {α}^{2 i} a + {α}^{2 j} b ) + {( {α}^{i} a + {α}^{j} b )}^{2} = \\ = {α}^{2 i} {a}^{2} + {α}^{2 i} ab + {α}^{2 j} ab + {α}^{2 j} {b}^{2} + {α}^{2 i} {a}^{2} + {α}^{2 j} {b}^{2} = \\ = ab ( {α}^{2 i} + {α}^{2 j} )\end{matrix} .$$

This yields

$$\begin{matrix}{σ}_{1} = \frac{{s}_{1} \cdot {s}_{4} + {s}_{2} \cdot {s}_{3}}{{s}_{1} \cdot {s}_{3} + {s}_{2}^{2}} = \\ = \frac{ab ( {α}^{3 i} + {α}^{3 j} + {α}^{i} {α}^{2 j} + {α}^{j} {α}^{2 i} )}{ab ( {α}^{2 i} + {α}^{2 j} )} = \\ = \frac{{α}^{i} \cdot {α}^{i} \cdot {α}^{i} + {α}^{j} \cdot {α}^{j} \cdot {α}^{j} + {α}^{i} \cdot {α}^{j} \cdot {α}^{j} + {α}^{i} \cdot {α}^{i} \cdot {α}^{j}}{{α}^{2 i} + {α}^{2 j}} = \\ = \frac{{α}^{2 i} \cdot ( {α}^{i} + {α}^{j} ) + {α}^{2 j} \cdot ( {α}^{i} + {α}^{j} )}{{α}^{2 i} + {α}^{2 j}} = \\ = {α}^{i} + {α}^{j}\end{matrix} , \qquad ( 87 )$$

In a Galois field GF(2^{m}), it holds true that adding two identical expressions yields the value 0. As such, for example

$${α}^{3 i} {a}^{2} + {α}^{3 i} {a}^{2} = 0.$$

It also holds true that

$${L}_{2} ( {α}^{i} ) = {L}_{2} ( {α}^{j} ) = 0 and {L}_{2} ( x ) \neq 0 for x \neq {α}^{i} , {α}^{j} .$$

One option is to determine σ₁ as a component-by-component XOR sum

$${σ}_{1} = {\sum }_{k = 0}^{n - 1} {δ}_{k} \cdot {α}^{k} \qquad ( 88 )$$

where

$${δ}_{k} = \{ \begin{matrix}1 & for {L}_{2} ( {α}^{k} ) = 0 \\ 0 & for {L}_{2} ( {α}^{k} ) \neq 0\end{matrix} \qquad ( 89 )$$

σ₁ is determined in accordance with equations (88) and (89) as the XOR sum of the two values of the Galois field GF(2^{m}) that correspond to the two zeros of the locator polynomial L₂(x).

One option is to use, instead of the locator polynomial from equation (84)

$${L}_{2} ( x ) = {x}^{2} + {σ}_{1} x + {σ}_{2}$$

a locator polynomial

$${L}_{2}^{′} ( y ) = {y}^{2} {σ}_{2} + y {σ}_{1} + 1 \qquad ( 90 )$$

Equation (90) is obtained by inserting

$$y = \frac{1}{x}$$

into equation (84). The zeros of L₂(y) are a⁻ⁱ and a^{-j} if the zeros of L₂(x) are equal to aⁱ and aⁱ.

For byte positions that are corrected in the event of a byte error, a byte error correction value is determined. If for example the byte positions 0 to n-1 are byte positions to be corrected, then a byte error value a(k) is determined for k where 0≤k≤n−1 in such a way that it holds true that:

$$a ( k ) = \frac{{s}_{2}}{{σ}_{1}} + {s}_{1} + \frac{{s}_{1}}{{σ}_{1}} {α}^{k} . \qquad ( 91 )$$

If there is a 2-byte error in the byte positions aⁱ and a^{j} with the byte error correction value a in the byte position aⁱ and the byte error correction value b in the byte position aⁱ, then it holds true for the i-th byte position where k=i according to equation (91) that

$$a ( i ) = \frac{{s}_{2}}{{σ}_{1}} + {s}_{1} + \frac{{s}_{1}}{{σ}_{1}} {α}^{i} = a$$

and for the j-th byte position where k=j according to equation (91) that

$$a ( j ) = \frac{{s}_{2}}{{σ}_{1}} + {s}_{1} + \frac{{s}_{1}}{{σ}_{1}} {α}^{i} = b .$$

In the byte positions in which there are no byte errors, the byte error correction value determined according to equation (91) is not used for correction. If the values at the byte positions i and j in the case of a 2-byte error are erroneous, then the values determined for k≠i and k≠j are not used for error correction. The byte error correction values a or b required for correction are provided at each of the byte positions k=i and k=j: in the case of the 2-byte error at the byte positions aⁱ and a^{j},

$${s}_{1} = a + b ,$$

$${s}_{2} = {α}^{i} a + {α}^{j} b$$

$${σ}_{1} = {α}^{i} + {α}^{j}$$

are inserted into equation (91), yielding:

$$\begin{matrix}a ( k ) = \frac{{α}^{i} a + {α}^{j} b}{{α}^{i} + {α}^{j}} + ( a + b ) + \frac{( a + b ) {α}^{k}}{{α}^{i} + {α}^{j}} = \\ = \frac{{α}^{i} a + {α}^{j} b + {α}^{i} a + {α}^{j} a + {α}^{j} a + {α}^{j} b + {α}^{k} a + {α}^{k} b}{{α}^{i} + {α}^{j}} = \\ = \frac{a ( {α}^{k} + {α}^{j} ) + b ( {α}^{k} + {α}^{i} )}{{α}^{i} + {α}^{j}} = \\ = \{ \begin{matrix}a & for & k = i \\ b & for & k = j\end{matrix} .\end{matrix}$$

It is advantageous that a technical implementation of the relationship indicated in equation (91) permits a clear simplification and therefore greater efficiency. As such, the values

$$\frac{{s}_{2}}{{σ}_{1}} + {s}_{1} \qquad ( 92 )$$

$$and$$

$$\frac{{s}_{1}}{{σ}_{1}} \qquad ( 93 )$$

can be formed centrally (in advance), for example, and possibly only once in each case, and reused to determine all of the byte positions to be corrected. Therefore, this example reduces the amount of processing/calculations required, and the correction of the byte positions can be performed more quickly (thereby enabling greater data throughput for the system, compared to other systems), and/or can be performed with fewer hardware gates and/or lower power than other systems.

By way of example, for each byte position k that is to be corrected, the value

$$\frac{{s}_{1}}{{σ}_{1}}$$

can be multiplied by the constant value ok known for the byte position k. The multiplication by the value a^{k} known for the byte position is a multiplication by a constant and can be realized using a simple constant multiplier.

The values

$$\frac{{s}_{2}}{{σ}_{1}} + {s}_{1} and \frac{{s}_{1}}{{σ}_{1}} \cdot {α}^{k}$$

can then be XORed component by component.

In contrast to methods known hitherto, it is therefore possible to save one inversion per byte in the Galois field GF(2^{m}).

One option is to use an H matrix H*

$${H}^{*} = ( \begin{matrix}{α}^{0} & {α}^{1} & … & {α}^{i} & … & {α}^{n - 1} \\ {α}^{0} & {α}^{2} & … & {α}^{2 \cdot i} & … & {α}^{2 \cdot [ n - 1 ]} \\ {α}^{0} & {α}^{3} & … & {α}^{3 \cdot i} & … & {α}^{3 \cdot [ n - 1 ]} \\ {α}^{0} & {α}^{4} & … & {α}^{4 \cdot i} & … & {α}^{4 \cdot [ n - 1 ]}\end{matrix} ) \qquad ( 94 )$$

The H matrix H* in accordance with equation (94) has four rows, whereas the H matrix H*_{Byte} in accordance with equation (2) comprises only three rows.

If there is a 2-byte error having the byte error values a and b at the byte positions i and j, the syndrome components s₁ to s₄ are obtained as

$${s}_{1} = {α}^{i} a + {α}^{j} b \qquad ( 95 )$$

$${s}_{2} = {α}^{2 i} a + {α}^{2 j} b$$

$${s}_{3} = {α}^{3 i} a + {α}^{3 j} b$$

$${s}_{4} = {α}^{4 i} a + {α}^{4 j} b$$

The H matrix H* according to equation (94) and the syndrome components in accordance with equation (95) are used to determine a byte error correction value a(k) for the k-th byte as follows:

$$a ( k ) = ( \frac{{s}_{2}}{{σ}_{1}} + {s}_{1} ) \cdot {α}^{- k} + \frac{{s}_{1}}{{σ}_{1}} \qquad ( 96 )$$

If there is a 2-byte error at the byte positions i and j with the byte error values a and b, then it holds true that a(i)=a and a(j)=b. This results from insertion of the syndrome components s₁ to sa in accordance with equation (95) into equation (85) and equation (96).

The implementation of the relationship in accordance with equation (96) permits a simplification compared with approaches known hitherto. As such, the values

$$\frac{{s}_{2}}{{σ}_{1}} + {s}_{1} \qquad ( 97 )$$

$$and$$

$$\frac{{s}_{1}}{{σ}_{1}} \qquad ( 98 )$$

can be formed centrally (in advance), for example, and possibly only once in each case, and reused to determine all of the byte positions to be corrected.

By way of example, for each byte position k that is to be corrected, the value

$$\frac{{s}_{2}}{{σ}_{1}} + {s}_{1}$$

can be multiplied by the constant value ok known for the byte position k, for example by using a constant multiplier.

The values

$$( \frac{{s}_{2}}{{σ}_{1}} + {s}_{1} ) \cdot {α}^{- k} and \frac{{s}_{1}}{{σ}_{1}}$$

can then be XORed component by component.

In contrast to methods known hitherto, it is therefore possible to save one inversion per byte in the Galois field GF(2^{m}).

In the case of a 2-byte error at the byte position aⁱ with the byte error value a and at the byte position a^{j} with the byte error value b, it holds true, independently of a and b, that

$${α}^{i} + {α}^{j} = \frac{{s}_{1} {s}_{4} + {s}_{2} {s}_{3}}{{s}_{1} {s}_{3} + {s}_{2}^{2}} . \qquad ( 99 )$$

This can be verified by inserting the syndrome components s₁ to s₄ in accordance with equation (95):

$$\begin{matrix}{σ}_{1} = \frac{{s}_{1} \cdot {s}_{4} + {s}_{2} \cdot {s}_{3}}{{s}_{1} \cdot {s}_{3} + {s}_{2}^{2}} = \\ = \frac{ab \cdot ( {α}^{i} {α}^{4 j} + {α}^{4 i} {α}^{j} + {α}^{2 i} {α}^{3 j} + {α}^{3 i} {α}^{2 j} )}{ab \cdot ( {α}^{i} {α}^{3 j} + {α}^{3 i} {α}^{j} )} = \\ = \frac{{α}^{i} \cdot ( {α}^{3 i} {α}^{j} + {α}^{i} {α}^{3 j} ) + {α}^{j} \cdot ( {α}^{i} {α}^{3 j} + {α}^{3 i} {α}^{j} )}{{α}^{i} {α}^{3 j} + {α}^{3 i} {α}^{j}} = \\ = {α}^{i} + {α}^{j}\end{matrix} . \qquad ( 100 )$$

When the H matrix H* in accordance with equation (94) is used, too, one option is to determine σ₁ as a component-by-component XOR sum

$${σ}_{1} = {\sum }_{k = 0}^{n - 1} {δ}_{k} \cdot {α}^{k} \qquad ( 101 )$$

where

$${δ}_{k} = \{ \begin{matrix}1 & for {L}_{2} ( {α}^{k} ) = 0 \\ 0 & for {L}_{2} ( {α}^{k} ) \neq 0\end{matrix}$$

holds true.

In the case of a 2-byte error in the byte positions i and j, the locator polynomial L₂(x) assumes the value 0 for x=aⁱ and for x=a^{j}, and a value not equal to 0 in all other byte positions, so that, according to equation (101), in the case of a 2-byte error at the byte positions i and j, it holds true that:

$${σ}_{1} = {α}^{i} + {α}^{j} .$$

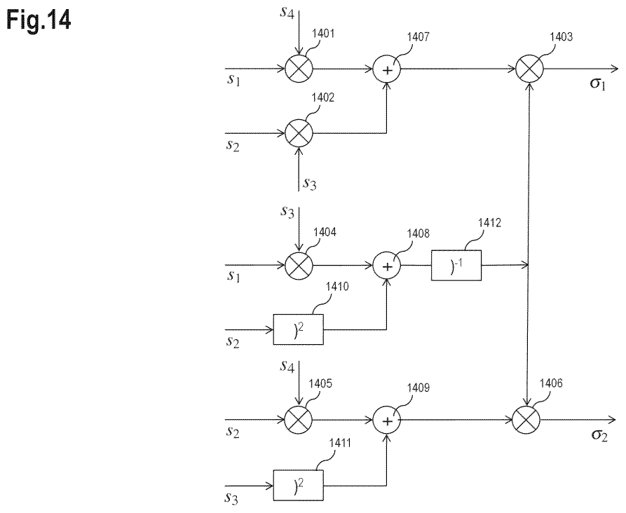

FIG. 14 shows an illustrative configuration for forming the coefficients σ₁ and σ₂ in accordance with equation (85) on the basis of the syndrome components s₁ to s₄ by using Galois field multipliers 1401 to 1406, adders (component-by-component XOR function) 1407 to 1409, squarers 1410, 1411 and an inverter 1412 (in the Galois field GF(2^{m})).

$$\frac{{s}_{1}}{{σ}_{1}} ,$$

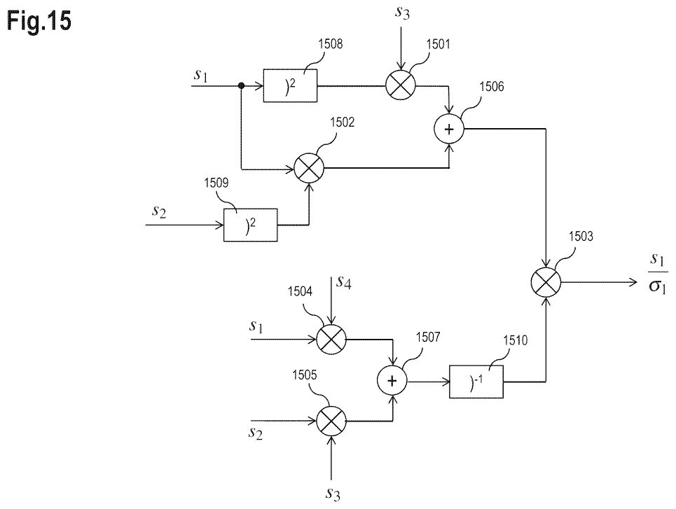

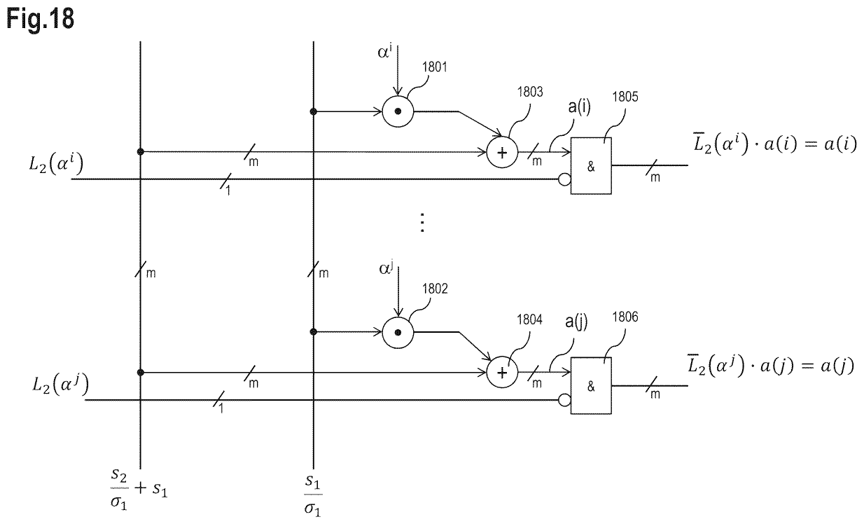

FIG. 15 shows an illustrative configuration for forming the term is an input signal for the circuit shown in FIG. 18. According to equation (85) which

$${σ}_{1} = \frac{{s}_{1} {s}_{4} + {s}_{2} {s}_{3}}{{s}_{1} {s}_{3} + {s}_{2}^{2}}$$

the result is therefore

$$\frac{{s}_{1}}{{σ}_{1}} = \frac{{s}_{1}}{\frac{{s}_{1} {s}_{4} + {s}_{2} {s}_{3}}{{s}_{1} {s}_{3} + {s}_{2}^{2}}} = \frac{{s}_{1}^{2} {s}_{3} + {s}_{1} {s}_{2}^{2}}{{s}_{1} {s}_{4} + {s}_{2} {s}_{3}} .$$

To this end, the circuit illustrated in FIG. 15 comprises Galois field multipliers 1501 to 1505, adders 1506 and 1507, squarers 1508 and 1509 and an inverter 1510.

$$\frac{{s}_{2}}{{σ}_{1}} + {s}_{1} ,$$

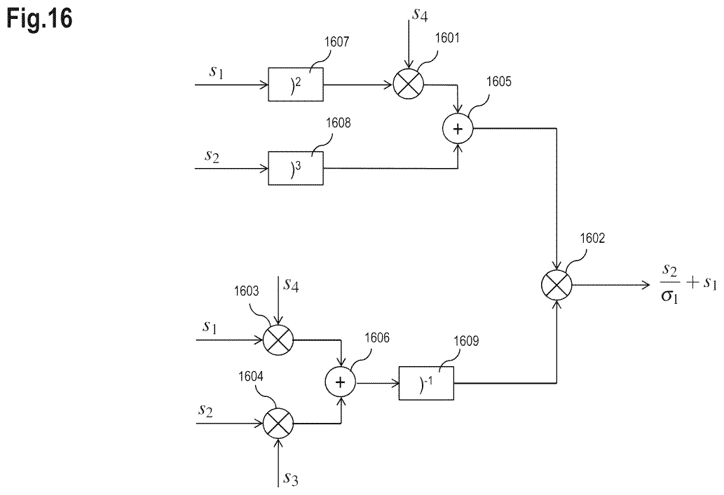

FIG. 16 shows an illustrative configuration for forming the term which is an input signal for the circuit shown in FIG. 18. Insertion with equation (85) again results in:

$$\begin{matrix}\frac{{s}_{2}}{{σ}_{1}} + {s}_{1} = \frac{{s}_{2}}{\frac{{s}_{1} {s}_{4} + {s}_{2} {s}_{3}}{{s}_{1} {s}_{3} + {s}_{2}^{2}}} + {s}_{1} = \\ = \frac{{s}_{1} {s}_{2} {s}_{3} + {s}_{2}^{3}}{{s}_{1} {s}_{4} + {s}_{2} {s}_{3}} + \frac{{s}_{1} ( {s}_{1} {s}_{4} + {s}_{2} {s}_{3} )}{{s}_{1} {s}_{4} + {s}_{2} {s}_{3}} = \\ = \frac{{s}_{1} {s}_{2} {s}_{3} + {s}_{2}^{3} + {s}_{1}^{2} {s}_{4} + {s}_{1} {s}_{2} {s}_{3}}{{s}_{1} {s}_{4} + {s}_{2} {s}_{3}} = \\ = \frac{{s}_{2}^{3} + {s}_{1}^{2} {s}_{4}}{{s}_{1} {s}_{4} + {s}_{2} {s}_{3}}\end{matrix} .$$

To this end, the circuit illustrated in FIG. 16 comprises Galois field multipliers 1601 to 1604, adders 1605 and 1606, a squarer 1607, a third power forming unit 1608 and an inverter 1609.

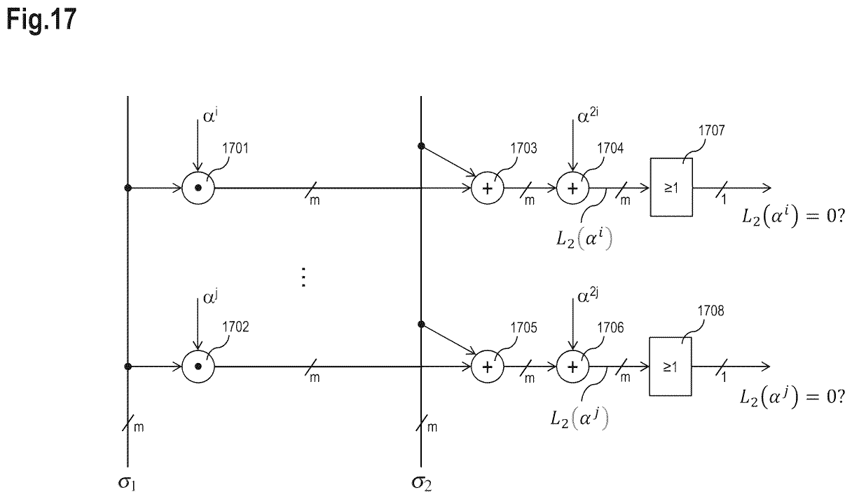

FIG. 17 shows an illustrative configuration for forming the values of the locator polynomial on the basis of its coefficients σ₁ and σ₂ for byte position i and j. If x is replaced by a^{k} in equation (84), then

$${L}_{2} ( {α}^{k} ) = {α}^{2 k} + {σ}_{1} \cdot {α}^{k} + {σ}_{2} . \qquad ( 102 )$$

FIG. 17 shows the determination of the locator polynomial in accordance with equation (102) for k=i, j. This is accomplished using, by way of illustration, constant multipliers 1701 and 1702, adders 1703 to 1706 and OR gates 1707 and 1708. The OR gate 1707, 1708 carries out an OR function for the signals present at the m inputs, so that the value 0 is present at the output only when the value 0 is present at all the inputs. The value 0 at the output of the respective OR gate therefore indicates whether the condition

$${L}_{2} ( {α}^{k} ) = 0 \qquad ( 103 )$$

is satisfied. As has been explained above, there is an error if this condition is satisfied.

FIG. 18 shows an illustrative configuration for forming the byte error correction values a(k) for the byte positions i and j based on the
locator polynomial L₂(a^{k}) determined and provided in accordance with FIG. 17
term s₂/σ₁+s₁ determined in accordance with FIG. 16 and
term s₁/σ₁ determined in accordance with FIG. 15.

This is accomplished in FIG. 18 using, by way of illustration, constant multipliers 1801 and 1802, adders 1803 to 1804 and AND gates 1805 and 1806, one of the inputs of the respective AND gate being inverted.

As was explained for FIG. 17, the value 0 indicates that the condition in accordance with equation (103) is satisfied. This means that an error has been able to be detected at the byte position k. Conversely, it holds true that no error was determined at the byte position k if

$${L}_{2} ( {α}^{k} ) \neq 0$$

holds true. Accordingly, the inverted value is applied to the input of the AND gate 1805, 1806 and therefore the byte error correction value

$$a ( k ) = \frac{{s}_{2}}{{σ}_{1}} + {s}_{1} + \frac{{s}_{1}}{{σ}_{1}} {α}^{k} .$$

in accordance with equation (91) is provided at the output of the AND gate 1805, 1806 only when a byte error has been detected at the byte position k by using the locator polynomial.

What is claimed is:

1. A circuit arrangement for correcting at least one byte error in a binary sequence comprising multiple bytes, the binary sequence being a codeword of an error code if there is no error, the circuit arrangement being configured
to determine a byte error position signal indicating whether or not a byte of the binary sequence is erroneous,
to determine a byte error correction value on the basis of which an erroneous byte position identified by the byte error position signal is able to be corrected,
wherein the byte error correction value is determined by determining a first value, a second value, and a third value for each of at least three byte positions according to a coefficient of a locator polynomial,
to correct the at least one byte error based on the byte error correction value.

2. The circuit arrangement as claimed in claim 1, in which the first value comprises: a correction value A multiplied by a first constant, the first constant being determined by the erroneous byte position.

3. The circuit arrangement as claimed in claim 2, in which the third value comprises: a correction value C multiplied by a second constant, the second constant being determined by the erroneous byte position.

4. The circuit arrangement as claimed in claim 3, in which the multiplications by the first constant and the second constant are multiplications in a Galois field GF(2^{m}) where m≥2.

5. The circuit arrangement as claimed in claim 4, in which the byte error correction value is determined in accordance with:
$$v ( L ) = {α}^{L} \cdot A + B + {α}^{2 L} \cdot C , \qquad ( 104 )$$
where
a^{L} denotes the first constant,
a^{2L} denotes the second constant,
A, C denotes the correction value A and the correction value C, respectively,
B denotes the second value, and
+denotes addition in the Galois field GF(2^{m}) where m≥2.

6. The circuit arrangement as claimed in claim 3, in which the correction value A, the correction value C, and the second value are the same for different byte positions.

7. The circuit arrangement as claimed in claim 3, in which the second constant is equa to the first constant squared.

8. The circuit arrangement as claimed in claim 1, in which a correction is made for byte positions for which the byte error correction value is not equal to zero.

9. The circuit arrangement as claimed in claim 1, in which a 3-byte error is able to be corrected using three byte error position signals.

10. The circuit arrangement as claimed in claim 1, in which at least some byte error correction values are determined at overlapping times.

11. The circuit arrangement as claimed in claim 1, in which the byte error position signal is able to be determined using components of an error syndrome of the error code.

12. The circuit arrangement as claimed in claim 1, in which the byte error correction value is determined for a correct byte.

13. The circuit arrangement as claimed in claim 1, in which a 3-byte error is corrected.

14. The circuit arrangement as claimed in claim 1, in which the error code is a Reed-Solomon code in a Galois field GF(2^{m}) where m≥2 that can correct at least 3-byte errors.

15. A method for correcting at least one byte error in a binary sequence comprising multiple bytes, the binary sequence being a codeword of an error code if there is no error, comprising:
determining a byte error position signal indicating whether or not a byte of the binary sequence is erroneous,
determining a byte error correction value on the basis of which an erroneous byte position identified by the byte error position signal is able to be corrected,
wherein the byte error correction value is determined by determining a first value, a second value, and a third value for each of at least three byte positions according to a coefficient of a locator polynomial,
correcting the at least one byte error based on the byte error correction value.
